(19) United States
(12) Patent Application Publication
(10) Pub. No.: US 2025/0069948 A1
(43) Pub. Date: Feb. 27, 2025

(54) DEPOSITION OF METALS IN RECESSED FEATURES WITH THE USE OF HALOGEN-CONTAINING DEPOSITION INHIBITORS

(71) Applicant: Lam Research Corporation, Fremont, CA (US)

(72) Inventors: David Joseph MANDIA, Fremont, CA (US); Ishtak KARIM, San Jose, CA (US); Kyle Jordan BLAKENEY, Milpitas, CA (US); Matthew Bertram Edward GRIFFITHS, Fremont, CA (US); Chiukin Steven LAI, Sunnyvale, CA (US)

(73) Assignee: Lam Research Corporation, Fremont, CA (US)

(21) Appl. No.: 18/714,506

(22) PCT Filed: Nov. 30, 2022
(86) PCT No.: PCT/US2022/080705

§ 371 Date: May 29, 2024

Related U.S. Application Data
(60) Provisional application No. 63/265,522, filed on Dec. 16, 2021.

(51) Int. Cl. H01L 21/768; C23C 16/08; C23C 16/455; C23C 16/52; H01L 21/3205

(52) U.S. Cl. CPC H01L 21/76826; C23C 16/08; C23C 16/45553; C23C 16/52; H01L 21/32051; H01L 21/76879

(57) ABSTRACT

Metal films, such as molybdenum films are deposited on a semiconductor substrate having one or more recessed features in a deposition process modulated by addition of a halogen-containing compound (e.g., an alkyl halide). In some implementations, a pre-treatment of a substrate with a halogen-containing compound is performed prior to contacting the substrate with a metal-containing precursor and a reducing agent. In some embodiments, the pre-treatment is performed such that the halogen-containing compound modifies the surface of the substrate to a greater degree in a field region of the substrate and near the opening of the recessed feature, as compared to the bottom portion of the recessed feature, where the modification of the substrate inhibits deposition of the metal. As a result, deposition of metals with improved step coverage can be achieved. In some implementations, modulation of deposition by halogen-containing compounds is used to achieve bottom-up metal growth in recessed features.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### FIELD OF THE INVENTION

This invention pertains to methods of semiconductor device manufacturing. Specifically, embodiments of this invention pertain to deposition of metals, such as molybdenum, in semiconductor processing.

### BACKGROUND

In semiconductor device fabrication, deposition and etching techniques are used for forming patterns of materials, such as for forming metal lines embedded in dielectric layers. Some patterning schemes require conformal deposition of materials, where the deposited layer should follow the contour of protrusions and/or recessed features on the surface of the substrate. Atomic layer deposition (ALD) is often a preferred method of forming conformal films on a substrate, because ALD relies on adsorption of one or more reactants (precursors) to the surface of the substrate, and on subsequent chemical transformation of the adsorbed layer to the desired material. Because ALD uses sequential reactions that occur on the surface of the substrate, that are separated in time, and that are typically limited by the amount of the adsorbed reactant, this method can provide thin conformal layers having excellent step coverage.

Chemical vapor deposition (CVD) is another deposition method widely used in semiconductor processing. In CVD, the reaction occurs in the volume of the process chamber and is not limited by the amount of reactants adsorbed to the substrate. As a result, CVD-deposited films are often less conformal than ALD-deposited films. CVD is typically used in applications where step coverage is less important.

ALD and CVD may employ plasma to promote the reactions of the deposition precursors resulting in the formation of the desired films. The methods that make use of the plasma are known as plasma enhanced ALD (PEALD) and plasma enhanced CVD (PECVD). The methods that do not employ plasma are referred to as thermal ALD and thermal CVD.

While ALD and CVD are most commonly used for deposition of silicon-containing films, such as silicon oxide, silicon nitride, and silicon carbide, these methods are also suitable for deposition of some metals.

The background description provided herein is for the purposes of generally presenting the context of the disclosure. Work of the presently named inventor, to the extent it is described in this background section, as well as aspects of the description that may not otherwise qualify as prior art at the time of filing, are neither expressly nor impliedly admitted as prior art against the present disclosure.

### SUMMARY

Methods for depositing metal films in recessed features of semiconductor substrates using inhibition of selected substrate surfaces to modulate deposition profile are provided. In some implementations, a halogen-containing deposition inhibitor is employed to lower the metal deposition rate at selected regions of the substrate (e.g., in the field region, and/or near the opening of the recessed features) and to thereby improve step coverage during metal deposition, or to achieve bottom-up metal fill of the recessed features. In some embodiments, the substrate is contacted with a halogen-containing inhibitor prior to contact with a metal precursor. In some embodiments the substrate is contacted contemporaneously with a metal precursor and with the halogen-containing inhibitor.

In one aspect a method of forming a metal layer on a semiconductor substrate is provided. In some embodiments the method includes: (a) providing a semiconductor substrate having a recessed feature; (b) exposing the semiconductor substrate to a deposition inhibitor, wherein the deposition inhibitor is a halogen-containing compound, and wherein the deposition inhibitor modifies a surface of the semiconductor substrate to make the surface more resistant to metal deposition than the surface was before modification; and (c) exposing the semiconductor substrate to a metal precursor and a reducing agent to form a metal layer at least within the recessed feature on the semiconductor substrate, wherein the metal precursor and the halogen-containing compound are different (are not the same compound). In some embodiments, the halogen-containing compound is an alkyl halide (e.g., a tertiary alkyl halide, such as t-butyl chloride). In some embodiments, the halogen-containing compound is an iodine-containing compound.

In some embodiments the semiconductor substrate is exposed to the deposition inhibitor prior to exposure to the metal precursor. In some embodiments the semiconductor substrate is exposed to the deposition inhibitor contemporaneously with the metal precursor. For example, the deposition inhibitor and the metal precursor can be co-flowed to a process chamber.

Provided methods can be used for deposition of a variety of metal layers, such as a molybdenum layer, a cobalt layer, a ruthenium layer, or any combination thereof. In one implementation, the deposited metal layer is a molybdenum layer and the metal precursor is a molybdenum precursor comprising a molybdenum-halogen bond. For example, the molybdenum precursor may include MoCl₅, Mo₂Cl₁₀, MoO₂Cl₂, or MoOCl₄, or any combination thereof. In some embodiments organometallic molybdenum precursors, such as halogen-free organometallic molybdenum precursors are used. An example of a halogen-free organometallic molybdenum precursor is bis(ethylbenxene)bolybdenum.

In some embodiments the deposition inhibitor modifies a surface on a field region and near an opening of the recessed feature to a greater degree than a surface of a bottom of the recessed feature. The modification can include, for example, at least one of physisorption and chemisorption. For example, in some embodiments the deposition inhibitor modifies the surface of the substrate by halogenating the surface of the substrate. The surface of the semiconductor substrate modified by the deposition inhibitor may include a metal, a metal nitride, a metal oxide, a metal carbide, metal silicide, amorphous silicon, polycristalline silicon, hydrogen-terminated silicon, silicon germanium, a silicon-containing dielectric, and any combination thereof. In one implementation the provided substrate comprises exposed metal nitride (e.g., titanium nitride), wherein the exposed metal nitride lines sidewalls of the recessed feature and a bottom of the recessed feature. The deposition inhibitor may modify the surface of the titanium nitride in the field region to a greater degree than at the bottom of the recessed feature.

In some embodiments the metal layer is deposited at a temperature of between about 250° C. and 600° C. (e.g. between about 350° C. and 600° C.) and a pressure of less than about 300 torr (e.g., less than about 200 torr).

In one implementation, after the semiconductor substrate has been exposed to the deposition inhibitor, the substrate is sequentially exposed to the metal precursor and a reducing agent, the sequential exposure to the metal precursor and the reducing agent is repeated to perform at least 10 inhibitor-free deposition cycles.

In another implementation the method comprises: (i) exposing the semiconductor substrate to the deposition inhibitor; (ii) after (i), exposing the semiconductor substrate to the metal precursor; (iii) after (ii) exposing the semiconductor substrate to a reducing agent to reduce the metal precursor to metal; and (iv) repeating steps (i)-(iii) to perform at least 10 inhibitor-assisted deposition cycles. In some embodiments each inhibitor-assisted deposition cycle includes a purging step after each of the exposure of the semiconductor substrate to the deposition inhibitor, exposure of the semiconductor substrate to the metal precursor, and the exposure of the semiconductor substrate to the reducing agent.

In some embodiments the metal layer is deposited conformally. In other embodiments the metal layer is deposited in a bottom-up deposition mode to fill the recessed feature.

In some embodiments the methods provided herein are integrated with photolithographic processing. For example, the methods may include the steps of: applying photoresist to the semiconductor substrate; exposing the photoresist to light; patterning the photoresist and transferring the pattern to the semiconductor substrate; and selectively removing the photoresist from the semiconductor substrate. For example, such photolithographic patterning may be used to form recessed features on the substrate prior to deposition of the metal layer.

In another aspect, an apparatus for processing a semiconductor substrate is provided, where the apparatus includes a controller having program constructions configured to cause performance of any of the methods provided herein. In some embodiments the apparatus includes: (a) a process chamber, having a substrate holder for holding a semiconductor substrate, and one or more inlets for introduction of reactants to the process chamber; and (b) a controller. The controller may include program instructions for: (i) causing contact of a semiconductor substrate having a recessed feature with a deposition inhibitor, wherein the deposition inhibitor is a halogen-containing compound, and wherein the deposition inhibitor modifies a surface of the semiconductor substrate to make the modified surface more resistant to metal deposition than the surface was before the modification; and (ii) causing contact of the semiconductor substrate with a metal precursor, and causing a reduction of the metal precursor to form a metal layer at least within the recessed feature on the semiconductor substrate, wherein the halogen-containing compound and the metal precursor are different.

In another aspect, a system is provided, wherein the system includes an apparatus provided herein and a stepper.

In another aspect, a non-transitory tangible computer machine-readable medium is provided, that includes program code for causing performance of any of the methods provided herein. For example it may include code configured for: (i) causing contact of a semiconductor substrate having a recessed feature with a deposition inhibitor, wherein the deposition inhibitor is a halogen-containing compound, and wherein the deposition inhibitor modifies a surface of the semiconductor substrate to make the modified surface more resistant to metal deposition than the surface was before the modification; and (ii) causing contact of the semiconductor substrate with a metal precursor, and causing a reduction of the metal precursor to form a metal layer at least within the recessed feature on the semiconductor substrate, wherein the halogen-containing compound and the metal precursor are different.

These and other aspects of implementations of the subject matter described in this specification are set forth in the accompanying drawings and the description below.

### BRIEF DESCRIPTION OF THE DRAWINGS

FIGS. 1A-1C illustrate schematic cross-sectional views of a substrate during deposition of metal films according to an embodiment provided herein.

FIGS. 1D-1F illustrate schematic cross-sectional views of a substrate during deposition of metal films according to another embodiment provided herein.

FIG. 2A is a process flow diagram for a method of forming metal films according to an embodiment provided herein.

FIG. 2B is a process flow diagram for a method of forming metal films according to an embodiment provided herein.

FIG. 2C is a process flow diagram for a method of forming metal films according to an embodiment provided herein.

FIG. 3 is a schematic illustration of a possible mechanism for inhibited deposition of molybdenum on a titanium nitride layer according to an embodiment provided herein.

FIG. 4 provides examples of ligands that can be used in molybdenum precursors according to an embodiment provided herein.

FIG. 5 provides examples of sulfur-containing ligands that can be used in molybdenum precursors according to an embodiment provided herein.

FIG. 6 lists examples of molybdenum precursors according to an embodiment provided herein.

FIG. 7 is a schematic presentation of an apparatus that is suitable for depositing metal films, according to an embodiment provided herein.

FIG. 8 shows a schematic view of a multi-station processing system according to an embodiment provided herein.

FIG. 9 shows a schematic view of a multi-station processing system according to an embodiment provided herein.

### DETAILED DESCRIPTION OF THE PREFERRED EMBODIMENTS

Methods for depositing metal films, such as molybdenum films, ruthenium films, tungsten films, and cobalt films, in recessed features of semiconductor substrates using gas phase deposition, such as CVD or ALD deposition, are provided. The methods utilize a halogen-containing deposition inhibitor to lower the metal deposition rate on selected surfaces of the substrate compared to what the deposition rate would have been without inhibition. In some implementations the deposition inhibition completely blocks metal growth on inhibitor-modified surfaces. In other implementations the metal deposition rate on inhibitor-modified surfaces is at least 1.5 times lower, such as at least 2 times lower, or at least 4 times lower than the deposition rate that would have been observed without inhibition. For example, ALD deposition without an inhibitor may deposit 0.4-0.8 Å of metal per ALD deposition cycle, while ALD deposition with inhibition, as provided herein, can lower the deposition rate to 0-0.2 Å of metal per ALD deposition cycle.

The inhibition can be used to control the deposition profile of the metal in the recessed features, as desired. For example, inhibition can be used to deposit conformal metal films (e.g., 1-10 nm thick) with excellent step coverage by selectively inhibiting deposition on those surfaces that would otherwise experience excessive unwanted deposition (e.g., field region, and areas near the opening of recessed features). The processes may then follow to fill the recessed features using conformal fill, which is characterized by substantially identical growth rates on sidewalls and bottom portions of the recessed features. In another example, inhibition of deposition in the field region and upper portion of the recessed feature, can be used to achieve bottom-up metal growth in the recessed feature, where the recessed feature may be filled with the metal, by depositing metal at the bottom of the feature at significantly higher rate than at feature sidewalls.

The halogen-containing deposition inhibitors provided herein can modify the surface of the substrate (e.g., via at least one of chemisorption and physisorption) to make the surface more resistant to metal growth. For example, alkyl halide treated surfaces can exhibit less metal nucleation compared to untreated surfaces.

In some embodiments the substrate is contacted with a halogen-containing deposition inhibitor such that there is a concentration gradient of the halogen-containing compound, and the more exposed field region surface of the semiconductor substrate is modified by the halogen-containing compound to a greater degree than a less exposed surface at the bottom of the recessed feature because the concentration of the halogen-containing compound in the field is greater than at the bottom of the recessed feature. The concentration gradient can be easily achieved by flowing a limited amount of the halogen-containing compound to the process chamber housing the semiconductor substrate and/or by limiting time of contact between the halogen-containing compound and the semiconductor substrate as desired. Further, in some embodiments, the top portion of sidewalls of the recessed feature is modified to a greater degree than a bottom portion of the sidewalls, e.g., the concentration of the alkyl halide at the top 20% of the sidewalls can be higher than at the feature bottom, and near the lower 20% of the sidewalls. This selective inhibition by the halogen-containing deposition inhibitor can be used to achieve deposition of metal in a conformal manner or for bottom-up deposition.

The halogen-containing deposition inhibitors can be used to inhibit deposition of metals on a variety of surfaces including but not limited to deposition on metals (e.g., molybdenum, tungsten, cobalt, ruthenium, copper, titanium and combinations thereof), metal nitrides (e.g., titanium nitride, tantalum nitride and combinations thereof), metal carbides (e.g., tungsten carbide), metal oxides (e.g., aluminum oxide, hafnium oxide, titanium oxide, and combinations thereof), metal silicides (e.g., titanium silicide) silicon (e.g., amorphous silicon, polycrystalline silicon, hydrogen-terminated silicon and combinations thereof), silicon germanium, silicon-containing dielectrics (e.g., silicon oxide, silicon nitride, silicon carbide, silicon oxynitride, silicon oxycarbide, and combinations thereof), carbon (e.g., amorphous carbon) and on any combination thereof.

The deposition is typically inhibited by exposing the substrate containing any of these materials to the halogen-containing compound and allowing the halogen-containing compound to adsorb to the surface. The halogen-containing compound can be flowed into a process chamber housing the substrate either by itself, or with at least one of an inert carrier gas, a metal precursor, and a reducing agent. Provided methods are useful for depositing metals on a substrate that has the same exposed material in the field region, on the sidewalls of a recessed feature and at the bottom of the recessed feature, because such substrates provide limited avenues for modulating deposition selectivity and profiles. However, provided methods are not restricted to such substrates, and can be used for depositing on substrates with dissimilar exposed materials. For example, provided methods can be used for depositing metals in a recessed feature having a silicon-containing dielectric (e.g., silicon oxide) exposed in the field region and on sidewalls of a recessed feature, and a metal (e.g., tungsten) exposed at the bottom of the recessed feature.

While provided methods can be used on substrates with different types of recessed features, including trenches, vias, contact holes and combinations thereof, the methods are particularly useful for deposition in recessed features with aspect ratios greater than 2:1, such as at least 5:1. In some embodiments provided methods are used for deposition of metals in high aspect ratio features with aspect ratios of at least 10:1 such as at least 50:1.

Provided methods can be used in a variety of applications including but not limited to deposition of metals (e.g. molybdenum) in gapfill applications, and formation of conformal metallic metal films. Examples of semiconductor device structures that can be manufactured using provided methods include back end of the line (BEOL) metallization structures, front end of the line (FEOL) metallization structures, logic metallization structures, and memory structures, such as 3D NAND and DRAM. In some embodiments the methods are used to deposit molybdenum-containing films having thicknesses ranging from between about 0.5 nm to about 4 nm, and can be used for depositing molybdenum metal in a variety of recessed features, such as features with widths of between about 1 nm and about 25 nm, depths of between about 30 nm and about 200 nm or more and a variety of aspect ratios including high aspect ratios of at least 10:1, such as 30:1.

“Metals” as used herein, refer to materials that consist essentially of metals in zero oxidation state. Other elements (e.g., C, N, or O) can be present in metals in small quantities (e.g., with a total content of less than about 15 atomic %, or less than about 10%, where hydrogen is not included in the calculation). It is noted that the use of alkyl halides does not result in incorporation of carbon into the resulting metal films, and metal films with less than 3% atomic of carbon can be obtained by provided methods. Example of metal films that can be obtained by provided methods include 97% pure molybdenum, 97% pure cobalt, 97% pure tungsten, and 97% pure ruthenium, where % refers to weight %.

The term “semiconductor substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The work piece may be of various shapes, sizes, and materials. In addition to semiconductor wafers, other work pieces that may take advantage of the disclosed implementations include various articles such as printed circuit boards and the like.

As used herein, the term “about” means+/−10% of any recited value, unless otherwise specified. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

As used herein, the phrase at least one of A, B, and C should be construed to mean a logical (A OR B OR C), using a non-exclusive logical OR, and should not be construed to mean ‘at least one of A, at least one of B, and at least one of C.

“A” as used herein should be construed as “one or more”. For example, “a surface of the substrate” should be construed as “one or more surfaces of the substrate”, and may include a recessed feature sidewall surface, a field surface, a recessed feature bottom surface, and combinations thereof.

A “reducing agent”, as used herein, refers to a reactant that loses one or more electrons in a reaction.

“Heteroleptic complexes”, as used herein, refer to compounds that contain at least two different ligands attached to a metal center.

“Homoleptic complexes”, as used herein, refer to compounds that contain all identical ligands attached to a metal center.

The term “inhibitor-free deposition cycle” refers to sequential exposure of the substrate to a metal precursor and a reducing agent without a deposition inhibitor.

The term “inhibitor-assisted deposition cycle” refers to exposure of the semiconductor substrate to a deposition inhibitor, a metal precursor, and a reducing agent, wherein at least some of these exposures are performed sequentially.

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O)H), acetyl (Ac or —C(O)Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O)Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group (—C(O)—). In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which L is an aryl group or an arylene group, as defined herein, and R is an alkyl group, as defined herein. In some embodiments, the alkenyl-aryl group is -L-R, in which L is an aryl group or an arylene group, as defined herein, and R is an alkenyl group, as defined herein. In some embodiments, the alkynyl-aryl group is -L-R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl (All), vinyl (Vi), 1-butenyl, 2-butenyl, and the like.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is -L-O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)—OAk, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₇, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl (Hx), heptyl (Hp), octyl (Oc), nonyl (Nn), decyl (De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22) —CO₂R′, where R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₈ aryl); (24) —SO₂R′, where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

“Alkyl halide” as used herein refers to a compound that includes one or more carbon-halogen bonds. Alkyl halides, as used herein, can be saturated compounds without double or triple carbon-carbon bonds, or unsaturated compounds (e.g., may include double and triple carbon-carbon bonds).

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. In other embodiments, the alkylene group is a C₂₋₃, C₂₋₆, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ or C₂₋₂₄ alkylsulfinylalkyl group (e.g., C₁₋₆ alkylsulfinyl-C₁₋₆ alkyl or C₁₋₁₂ alkylsulfinyl-C₁₋₁₂ alkyl). In other embodiments, the alkylsulfinylalkyl group is -L-S(O)—R, in which each of L and R is, independently, an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is -L-SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16° C. to 26° C., such as from 19° C. to 25° C. or from 20° C. to 25° C.

By “amide” is mean —C(O)NR¹R² or —NHCOR¹, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant —NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof; or R¹ and R², taken together with the nitrogen atom to which each are attached, can form a heterocyclyl group, as defined herein; and each of R³ and R⁴ is, independently, H or alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—). In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., -L¹-NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₃₋₈ cycloalkyl-C₁₋₆ alkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R′)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R′)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., ═O); (34) C₁₋₆ thioalkyl (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₄₋₁₈ aryl-C₁₋₆ alkyl (e.g., -L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₄₋₁₈ aryl-C₁₋₆ alkyl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₁₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group. By “aryl-alkyl,” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₈ aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₁₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₁₈ aryl-C₂₋₆ alkynyl). In some embodiments, the aryl-alkyl group is -L-R, in which L is an alkyl group or an alkylene group, as defined herein, and R is an aryl group, as defined herein.

In some embodiments, the aryl-alkenyl group is -L-R, in which L is an alkenyl group or an alkenylene group, as defined herein, and R is an aryl group, as defined herein. In some embodiments, the aryl-alkynyl group is -L-R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group. In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-N₃, in which L is an alkyl group, as defined herein.

By “azo” is meant an —N═N— group.

By “carbamoyl” is meant an amino group attached to the parent molecular group through a carbonyl group, as defined herein. In some embodiments, the carbamoyl is —C(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O-L-R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl. Further, cycloalkyl may include one or more double bonds and/or triple bonds.

By “cycloheteroaliphatic” is meant a heteroaliphatic group, as defined herein, that is cyclic.

By “disilanyl” is meant a group containing an Si—Si bond. In some embodiments, the disilanyl group is a —SiR^{S1}R^{S2}—SiR^{S3}R^{S4}R^{S5} or —SiR^{S1}R^{S2}—SiR^{S3}R^{S4}-group, in which each of R^{S1}, R^{S2}, R^{S3}, R^{S4}, and R^{S5} is, independently, H, optionally substituted aliphatic, optionally substituted heteroaliphatic, optionally substituted aromatic, optionally substituted heteroaromatic, or optionally substituted amino.

By “disulfide” is meant —SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “chalcogen” is meant, O, S, Se or Te.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxycarbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein.

By “heteroaromatic-oxycarbonyl” is meant a heteroaromatic group that is or can be coupled to a compound disclosed herein, wherein the heteroaromatic group is or becomes coupled through an oxycarbonyl group (—C(O)O—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant —NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof; or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R′)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹)R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR¹)H, —C(NR¹)R^{Ak}, or —C(NR^{N1})R^{Ar}, in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{Ak} is an optionally substituted alkyl or an optionally substituted aliphatic; and R^{Ar} is an optionally substituted aryl or an optionally substituted aromatic.

By “imino” is meant a —NR— group. In some embodiments, R is selected from hydrogen, optionally substituted aliphatic, optionally substituted heteroaliphatic, optionally substituted aromatic, or optionally substituted heteroaromatic. In particular embodiments, R is H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt).

Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl By “sulfinyl” is meant an —S(O)— group.

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

Other features and advantages of the invention will be apparent from the following description and the claims.

The term “independently selected”, when referring to R substituent selection in a molecule containing multiple R groups, means that the selection of R substituents at different atoms of a molecule is independent and that the selection of R substituents at one atom having multiple R substituents is also independent.

### EMBODIMENTS

In some embodiments, the deposition method provided herein involves providing a semiconductor substrate having a recessed feature, and exposing the substrate to a halogen-containing deposition inhibitor, where the deposition inhibitor modifies a surface of the substrate to make it more resistant to metal deposition. The process further involves exposing the semiconductor substrate to a metal precursor and a reducing agent, where the reducing agent reduces the metal precursor to metal in zero oxidation state.

When deposition of metals in recessed features is conducted in an absence of a deposition inhibitor, the metal can deposit at a greater deposition rate in the field region of the substrate as compared to the bottom portion of the recessed feature, or bottom portions of feature sidewalls. This may happen due to slower diffusion of metal precursor to the bottom of the recessed feature, which may create locally higher concentration of metal precursor near the field region than at the bottom of the recessed feature. Further, in some instances the deposition of metal occurs at a greater rate at the sidewalls near the opening of the recessed feature than at the sidewalls near the bottom of the recessed feature. The use of a halogen-containing deposition inhibitor can inhibit the deposition on the field region and near the opening of the recessed feature and can lead to deposition with excellent step coverage. For example, conformal metal layers may be deposited using methods provided herein. Conformal metal films where a ratio of deposited metal thickness at a recessed feature sidewall to deposited metal thickness on the field is at least 90%, such as at least 95%, can be obtained.

In the following Figures embodiments are illustrated using an alkyl halide deposition inhibitor as an example. It is understood that alkyl halide is used for illustration purposes, and a variety of halogen-containing compounds may be used as deposition inhibitors in the depicted embodiments. Examples of deposition inhibitors include dihalogens (e.g., F₂, Cl₂, Br₂ and I₂), hydrogen halides (e.g., HF, HCl, HBr, HI), metal halides, boron halides, germanium halides, compounds containing silicon-halogen bond, compounds containing carbon-halogen bond, and compounds containing nitrogen-halogen bond. In some embodiments, the halogen-containing compound is one or more of X₂ (dihalogen), HX (hydrogen iodide), CH₃X (methyl halide), C₂H₅X (ethyl halide), 1-halopropane, 2-halopropane, 1-halobutane, sec-butyl halide, t-butyl halide, halocyclopentane, halocyclohexane, halodomethane, 1,2-dihaloethane, 1,1-dihalopropane, 1,2-dihalopropane, 1,3-dihalopropane, 2,2-dihalopropane, 1,1-dihalobutane, 1,2-dihalobutane, 1,3-dihalobutane, 2,2-dihalobutane, 2,3-dihalobutane, 1,2-dihalo-2-methylpropane, 2,3-dihalo-2,3-dimethylbutane, 1,1,2,2-tetrahaloethane, 2,2,3,3-tetrahalobutane, 1,1,1,2,2,2-hexahaloethane, 1,2-dihalocyclopentane, 1,2-dihalocyclohexane, halobenzene, dihalobenzene, 2-halopyridine, 3-halopyridine, 4-halopyridine, 3-halo-1-nitrobenzene, 3-halo-1-trifluoromethylbenzene, 4-haloaniline, 4-halo-1-dimethylaminobenzene, 4-halophenol, (trimethylsilyl)methyl halide, (trimethylsilyl)methyl dihalide, (trimethylsilyl)methyl trihalide, bis(trimethylsilyl)methyl halide, bis(trimethylsilyl)methyl dihalide, tris(trimethylsilyl)methyl halide, 1-(trimethylsilyl)-1-haloethane, 1-(trimethylsilyl)-1,2-dihaloethane, 1,1-bis(trimethylsilyl)-1,2-dihaloethane, 1,2-bis(trimethylsilyl)-1,2-dihaloethane, CHX₃ (trihalomethane), CX₄ (carbon tetrahalide), 1-haloethene, 1-halopropene, 2-halopropene, 1-halo-1-butene, 1-iodo-2-butene, 2-halo-1-butene, 2-halo-2-butene, haloacetylene, 3,3-dimethyl-1-halo-but-1-yne, 1,1-dihaloethene, 1,2-dihaloethene, 1,2-dihalopropene, 1,2-dihalo-2-propene, 1,2-dihalobutene, 1,2-dihalo-2-butene, 1,2-dihalo-3-butene, 3,4-dihalocyclohexene, 4,5-dihalocyclohexadiene, 1,2-dihaloacetylene, 1,1,2,2-tetrahaloethene, SiX₄ (silicon tetrahalide), SiHX₃ (trihalosilane), SiH₂X₂ (dihalosilane), SiH₃X (halosilane), Si(CH₃)X₃ (methylsilyl trihalide), Si(CH₃)₂X₂ (dimethylsilyl dihalide), Si(CH₃)₃X (trimethylsilyl halide), Si(CH₃)HX₂ (dihalomethylsilane), Si(CH₃)₂HX (halodimethylsilane), Si(CH₃)H₂X (methylhalosilane), Si₂X₆ (hexahalodisilane), GeX₄ (germanium tetrahalide), GeHX₃ (trihalogermane), GeH₂X₂ (dihalogermane), GeH₃X (halogermane), AlX₃ (aluminum trihalide), BX₃ (boron trihalide), TiX₄ (titanium tetrahalide), SnX₄ (tin tetrahalide), N-halosuccinimide, 1,3-dihalo-5,5-dimethylhydantoin, N-halophthalimide, N-halosaccharin, and 1-chloro-2-haloethane, wherein X (and halo) is a halogen independently selected from F, Cl, Br, and I.

In some embodiments iodine-containing halogen-containing compounds are used as deposition inhibitors. Examples of iodine-containing compounds include 12 (diiodine), HI (hydrogen iodide), CH₃I (methyl iodide), C₂H₅I (ethyl iodide), 1-iodopropane, 2-iodopropane, 1-iodobutane, sec-butyl iodide, t-butyl iodide, iodocyclopentane, iodocyclohexane, diiodomethane, 1,2-diiodoethane, 1,1-diiodopropane, 1,2-diiodopropane, 1,3-diiodopropane, 2,2-diiodopropane, 1,1-diiodobutane, 1,2-diiodobutane, 1,3-diiodobutane, 2,2-diiodobutane, 2,3-diiodobutane, 1,2-diiodo-2-methylpropane, 2,3-diiodo-2,3-dimethylbutane, 1,1,2,2-tetraiodoethane, 2,2,3,3-tetraiodobutane, 1,1,1,2,2,2-hexaiodoethane, 1,2-diiodocyclopentane, 1,2-diiodocyclohexane, iodobenzene, diiodobenzene, 2-iodopyridine, 3-iodopyridine, 4-iodopyridine, 3-iodo-1-nitrobenzene, 3-iodo-1-trifluoromethylbenzene, 4-iodoaniline, 4-iodo-1-dimethylaminobenzene, 4-iodophenol, (trimethylsilyl)methyl iodide, (trimethylsilyl)methyl diiodide, (trimethylsilyl)methyl triiodide, bis(trimethylsilyl)methyl iodide, bis(trimethylsilyl)methyl diiodide, tris(trimethylsilyl)methyl iodide, 1-(trimethylsilyl)-1-iodoethane, 1-(trimethylsilyl)-1,2-diiodoethane, 1,1-bis(trimethylsilyl)-1,2-diiodoethane, 1,2-bis(trimethylsilyl)-1,2-diiodoethane, CHI₃ (triiodomethane), CI₄ (carbon tetraiodide), 1-iodoethene, 1-iodopropene, 2-iodopropene, 1-iodo-1-butene, 1-iodo-2-butene, 2-iodo-1-butene, 2-iodo-2-butene, iodoacetylene, 3,3-dimethyl-1-iodo-but-1-yne, 1,1-diiodoethene, 1,2-diiodoethene, 1,2-diiodopropene, 1,2-diiodo-2-propene, 1,2-diiodobutene, 1,2-diiodo-2-butene, 1,2-diiodo-3-butene, 3,4-diiodocyclohexene, 4,5-diiodocyclohexadiene, 1,2-diiodoacetylene, 1,1,2,2-tetraiodoethene, SiI₄ (silicon tetraiodide), SiHI₃ (triiodosilane), SiH₂I₂ (dioiodosilane), SiH₃I (iodosilane), Si(CH₃)I₃ (methylsilyl triiodide), Si(CH₃)₂I₂ (dimethylsilyl dioiodide), Si(CH₃)₃I (trimethylsilyl iodide), Si(CH₃)HI₂ (diiodomethylsilane), Si(CH₃)₂HI (iododimethylsilane), Si(CH₃)H₂I (methyliodosilane), Si₂I₆ (hexaiododisilane), GeI₄ (germanium tetraiodide), GeHI₃ (triiodogermane), GeH₂I₂ (diiodogermane), GeH₃I (iodogermane), AlI₃ (aluminum triiodide), BI₃ (boron triiodide), TiI₄ (titanium tetraiodide), SnI₄ (tin tetraiodide), N-iodosuccinimide, 1,3-diiodo-5,5-dimethylhydantoin, N-iodophthalimide, N-iodosaccharin, 1-chloro-2-iodoethane, and iodinechloride (IC).

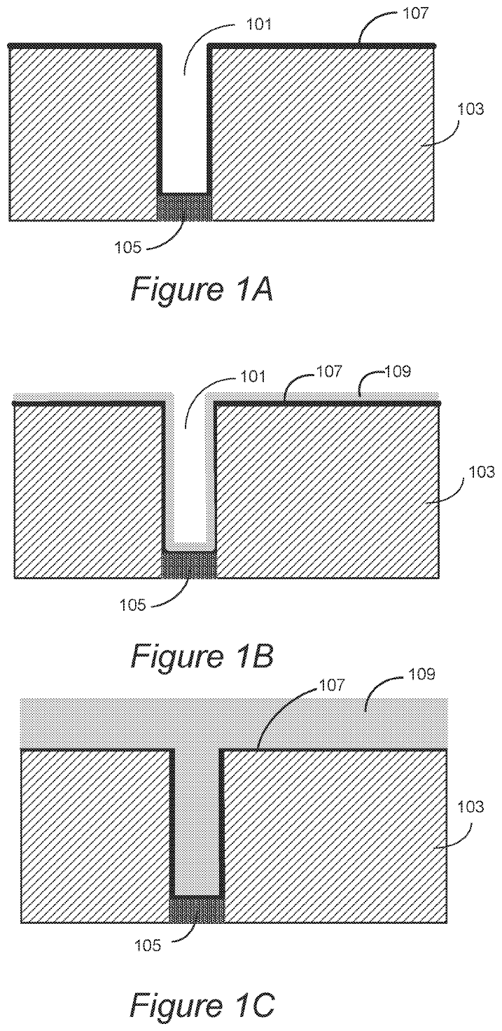

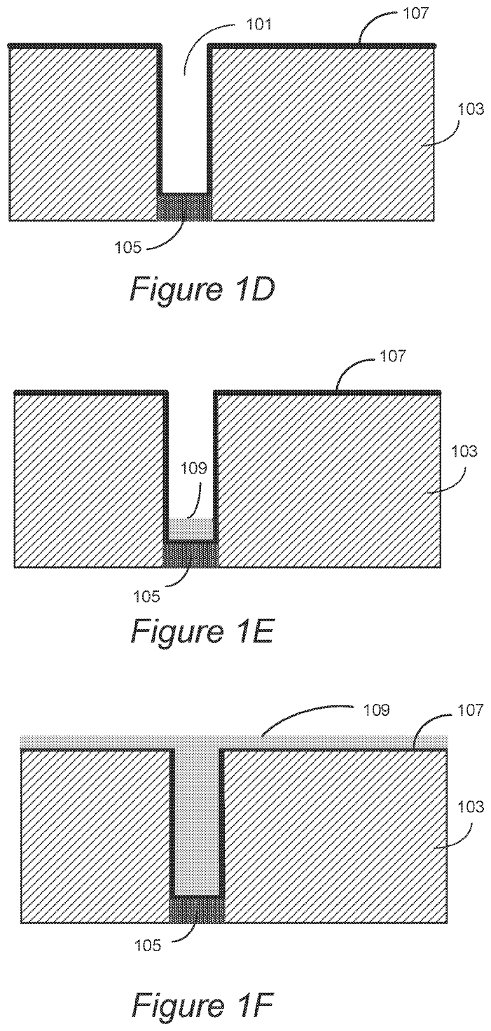

FIGS. 1A-1C illustrate schematic cross-sectional views of a semiconductor substrate undergoing metal deposition according to methods provided herein, where conformal deposition of metal film is illustrated. Figure TA illustrates a substrate having a recessed feature 101 formed in a layer of material 103, which may be a silicon-containing dielectric layer, such as silicon oxide. A layer 105 which may include metal silicide and silicon is residing at the bottom of the recessed feature 101. The substrate is lined with a titanium nitride layer, which is exposed in the field region, on the sidewalls of the recessed feature, and at the bottom of the recessed feature. If metal deposition is carried out on such substrate without using an inhibitor, by sequentially or concurrently exposing the substrate to metal precursor and a reducing agent, a substantially thicker layer of metal will be deposited in the field region than at the bottom of recessed feature, and feature sidewalls, because the field region is more exposed and there would be more metal nucleation in the field. According to methods provided herein, the substrate is exposed to an alkyl halide deposition inhibitor, where the alkyl halide modifies the surface of the substrate in the field region more than at the bottom of the recessed feature (e.g., due to alkyl halide concentration gradient). After the surface has been modified by the alkyl halide, the semiconductor substrate is exposed to a metal precursor and a reducing agent (e.g., with repetition of sequential exposures) to reduce the metal precursor and form a conformal layer of metal 109, as illustrated in FIG. 1B. The process then may follow to fill the recessed feature 101 with metal by exposing the semiconductor substrate to a metal precursor and a reducing agent (e.g., with repetition of sequential exposures). In some embodiments, exposure of the substrate to an alkyl halide deposition inhibitor is further included during metal deposition in addition to the initial pre-treatment of the substrate provided in Figure TA. For example, the substrate may be exposed to the alkyl halide deposition inhibitor in each metal deposition cycle, or after a pre-determined number of deposition cycles to allow for modulation of deposition profile (e.g., to reduce deposition in the field region). The structure obtained after the feature 101 has been filled with metal 109 is shown in FIG. 1C.

In another embodiment the use of an alkyl halide deposition inhibitor allows for bottom-up deposition of metal. In this embodiment, the surfaces of the field and sidewalls are sufficiently modified by exposure to the alkyl halide inhibitor to reduce metal growth on these surfaces to negligible numbers, whereas the bottom of the recessed feature is less modified, and metal growth rate on the bottom is substantially higher than the metal growth rate on the sidewalls and in the field. For example, the metal deposition rate on the bottom may be at least 1.5 times, such as at least about 2 times or at least about 5 times greater than on the inhibited surfaces (e.g. field or sidewalls). This is illustrated in FIGS. 1D-1F, where FIG. 1D shows the substrate provided for metal deposition, which is the same substrate as shown in FIG. 1A. The substrate shown in FIG. 1A is exposed to an alkyl halide deposition inhibitor, which modifies the field region to a greater extent than the bottom of the recessed feature, and metal is deposited according to methods provided herein. FIG. 1E illustrates the substrate after a portion of metal 109 has been deposited in a bottom-up deposition using inhibition by the alkyl halide inhibitor as described herein. The metal deposition process may follow in bottom-up fashion to fill the recessed feature 101, and provide a substrate with a filled recess, as shown in FIG. 1F.

The inhibition of metal deposition on selected surfaces can be carried out using a variety of process sequences, and can be integrated into both CVD and ALD metal deposition processes. In CVD processes the metal precursor and the reducing agent are delivered to the process chamber contemporaneously at least during some time during the deposition. In ALD processes the metal precursor and the reducing agent are delivered to the process chamber sequentially, without contemporaneous delivery. In ALD, the deposition cycles, where each cycle includes a metal precursor delivery phase and a reducing agent delivery phase, are repeated as many times as necessary to form a metal film of desired thickness.

The metal depositions in the depicted examples can be carried out at temperatures of between about 250° C. and about 600° C. (such as between about 350° C. and about 600° C.), and pressures of typically less than 300 torr, such as between about 0.1 and about 100 torr. The metal precursors, the reducing agents and alkyl halide inhibitors are selected such that they can be introduced in a vapor form under deposition conditions. In some embodiments both the inhibition step and metal reduction step are carried out in the same process chamber or process station of a deposition apparatus. In other embodiments, alkyl halide surface pre-treatment is conducted in a different process chamber or process station than the metal precursor exposure and reduction. The reactants (the inhibitor, the metal precursor, and a reducing agent) can be flowed into process chamber with flow rates ranging, for example from 0.5-10,000 sccm depending on the implementation, with or without use of inert carrier gasses. In some embodiments, the deposition involves sequentially exposing the substate to an alkyl halide, a metal precursor, and a reducing agent, where each exposure lasts between about 1 and about 200 seconds, such as between about 5-50 seconds. In one exemplary implementation, the deposition process utilizes t-butyl chloride as an alkyl halide inhibitor, MoCl₅ as a metal precursor for deposition of molybdenum, and H₂ as a reducing agent. In some embodiments, exposure to the reducing agent (e.g., hydrogen) is carried out at a higher pressure than exposure to the alkyl halide, and a metal precursor. In some embodiments, an exposure to an alkyl halide is longer than each of the exposures to a metal precursor or a reducing agent.

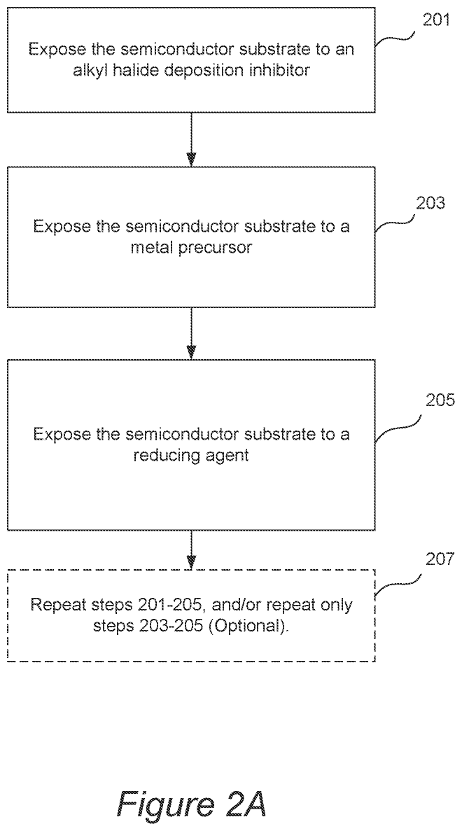

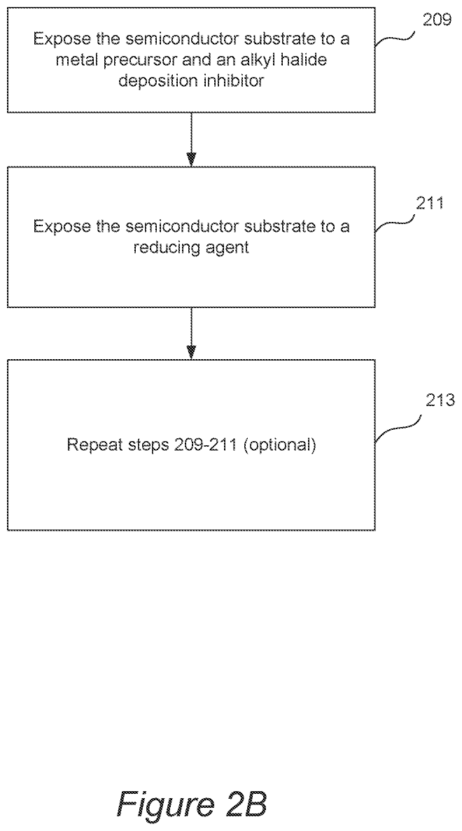

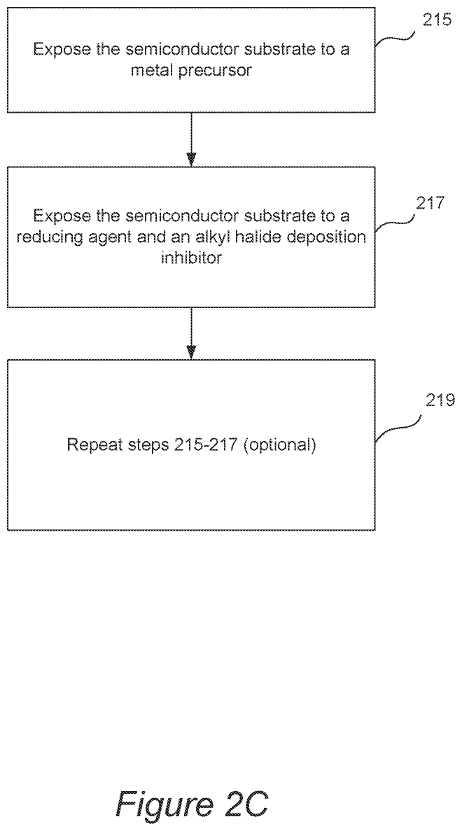

Different exemplary process flows for metal deposition methods with the use of alkyl halide inhibition are illustrated in FIGS. 2A-2C. These methods can be used for conformal or bottom-up metal deposition on a variety of substrates with recessed features as described herein.

In some embodiments, the inhibition with an alkyl halide inhibitor is integrated into an ALD process, illustrated by the process flow diagram shown in FIG. 2A. The process starts by exposing the substrate to an alkyl halide deposition inhibitor in step 201. The substrate may be any of the substrates described herein, such as a substrate with an exposed metal layer, metal nitride layer, metal oxide layer, silicon layer, or silicon-containing dielectric layer. For example, the substrate may have a structure shown in FIG. 1A, with an exposed titanium nitride layer lining the surface of the substrate in the field region, on feature sidewalls and at the feature bottom. When the substrate is exposed to alkyl halide, the alkyl halide modifies the field region to a greater degree than the bottom of the feature and makes the modified surfaces more resistant to subsequent deposition than these surfaces were before modification. In some embodiments the alkyl halide inhibitor is flowed to the process chamber in an absence of any co-flowing gasses. In other embodiments the alkyl halide inhibitor is flowed to the process chamber with an inert carrier gas, such as nitrogen, argon, or helium. The alkyl halide is flowed under process conditions that allow it to adsorb to the surface of the substrate and modify the surface, where the adsorption may involve at least one of physisorption and chemisorption (e.g., surface halogenation). Next, the flow of the alkyl halide is stopped, and, in step 203, the substrate is exposed to a metal precursor. The metal precursor can be introduced to the process chamber with or without a carrier gas and is allowed to adsorb to the surface of the substrate. As it has been described, the adsorption of the metal precursor is hindered by the presence of the inhibitor-induced modification on the surface. After the flow of the metal precursor is stopped, the process continues in step 205, in which the substrate is exposed to a reducing agent, where the reducing agent reduces the adsorbed metal precursor on the surface of the substrate, to form a metal layer. After the flow of the reducing agent is stopped, the process may continue in step 207 by repeating steps 201-205, or by repeating only steps 203-205, or by repeating steps 201-205 in a portion of deposition cycles and only steps 203-205 in another portion of deposition cycles.

In some embodiments, the initial pre-treatment 201 with the alkyl halide deposition inhibitor is sufficient to modify the deposition profile as desired, and subsequent deposition cycles do not include alkyl halide treatment. For example, the provided substrate may be treated with alkyl halide, and the process may follow by performing 2-2,000 deposition cycles, where each cycle has one metal precursor exposure step and one reducing agent exposure step. In some embodiments 2-200 of such deposition cycles are performed. This embodiment is referred to as an alkyl halide pre-soak deposition, since alkyl halide treatment is only used in the beginning of the process, but is not part of each of the repeating deposition cycle.

In other embodiments, it is advantageous to treat the substrate with alkyl halide deposition inhibitor in each deposition step. For example, one deposition cycle may include alkyl halide exposure, metal precursor exposure, and a reducing agent exposure. The deposition process, in some embodiments, involves performing 2-2,000 such cycles, for example 2-200 such cycles. This embodiment is referred to as a three-step cycle deposition.

In some embodiments the deposition process includes both two-step deposition cycles (metal precursor and reducing agent exposure phases in an absence of alkyl halide) and three-step deposition cycles (alkyl halide, metal precursor and reducing agent exposure phases). In some embodiments, the alkyl halide exposure step is inserted after a pre-determined number of two-step deposition cycles to modify the deposition profile as desired.

It is noted that the process flow shown in FIG. 2A can be conducted with or without purging between exposure phases. In some embodiments the process chamber is purged with an inert gas, such as nitrogen, argon, or helium after each of alkyl halide exposure step 201, metal precursor exposure step 203, and reducing agent exposure step 205. Deposition with purging is preferred for deposition in high aspect ratio recessed features in some embodiments.

The alkyl halide deposition inhibitor is capable of inhibiting metal deposition even if it is introduced contemporaneously with the metal-containing precursor. For example, in the process flow illustrated in FIG. 2B, the process starts in step 209 by exposing the substrate to an alkyl halide deposition inhibitor and to a metal precursor. For example, the alkyl halide and the metal precursor can be flowed contemporaneously to the process chamber housing the substrate either through separate inlets to the process chamber or through a single inlet in a pre-mixed form. The alkyl halide modifies the surface of the substrate, such that selected portions of the surface become more resistant to metal deposition. For example, as discussed above, due to alkyl halide concentration gradient the surface may be modified to greater extent in the field region and near the opening of the recessed feature than at the bottom of the recessed feature. Next, the flow of the alkyl halide and of the metal precursor is stopped, and in step 211 the substrate is exposed to a reducing agent (flowed without the metal precursor and without alkyl halide). After the reducing agent reduces the metal precursor to form a metal layer, steps 209 and 211 may be repeated in step 213 as many times as desired to form a metal film of desired thickness. For example, 2-2,000 deposition cycles, such as 2-200 deposition cycles may be performed, where each cycle includes step 209 and step 211. In some embodiments, the process may start by repeating steps 209 and 211 for a number of deposition cycles and then continue with inhibitor-free cycles that include only steps 203 and 205. Purging may be optionally used in each deposition cycle after each of steps 209 and 211.

In another embodiment, the inhibitor is introduced contemporaneously with the reducing agent. This is illustrated by the process flow diagram shown in FIG. 2C. The process starts in step 215 by exposing the substrate to a metal precursor. Next, in step 217, the substrate is exposed contemporaneously to a reducing agent and an alkyl halide deposition inhibitor. The process may follow in step 219 by repeating steps 215 and 217. For example, 2-2,000 deposition cycles, such as 2-200 deposition cycles may be performed, where each cycle includes step 205 and step 217. Purging with an inert gas may be optionally conducted after each of steps 205 and step 217.

In some embodiments the order of exposure of the substrate to the reducing agent and metal precursor may be switched (as compared to the order shown in FIGS. 2A-2C). In some embodiments, the processes further involve hydrogen (H₂) treatment of the surface of the substrate immediately prior to initiating the deposition processes shown in FIGS. 2A-2C, where hydrogen may further condition the surface for deposition.

In other embodiments, the treatment with an alkyl halide inhibitor is integrated into a CVD process. For example, the substrate may be contacted with an alkyl halide inhibitor, prior to being exposed contemporaneously to metal precursor and a reducing agent.

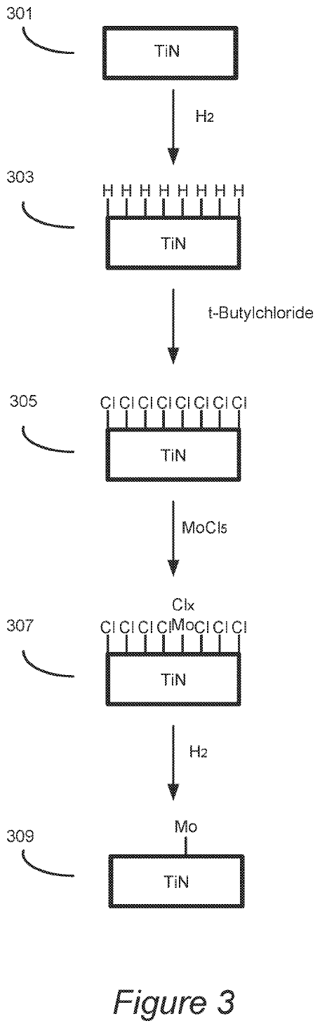

Without being limited by a particular theory, or by a specific inhibition mechanisms, it is suggested that inhibition may occur due to halogenation of the substrate surface by the alkyl halide, where halogenation, in turn, limits adsorption of metal precursor on that surface. This mechanism is illustrated in FIG. 3, which schematically presents a substrate surface undergoing molybdenum deposition. In the depicted example, a substrate containing a titanium nitride layer 301 is provided. Next, the substrate is treated with hydrogen (H₂) in a surface conditioning operation, which also forms hydrogen-terminated surface 303 on the titanium nitride layer. Next, the substrate is exposed to t-butyl chloride, resulting in a formation of chlorinated titanium nitride surface 307, and concurrent formation of 2-methylpropene (not shown). The substrate is then exposed to MoCl₅ molybdenum precursor, which is adsorbed to the chlorinated surface with difficulty, as compared to an untreated surface. Thus, the formation of halogenated surface leads to nucleation delay in metal growth. Next, the substrate is treated with a reducing agent, and the adsorbed molybdenum precursor is reduced to molybdenum metal, while chlorine atoms are concurrently removed from the surface resulting in a surface 309 with sparse growth of molybdenum. It is noted that physisorption of alkenes (such as 2-methylpropene) that form after elimination of hydrogen halides from alkyl halides may also contribute to inhibition of metal nucleation on the surface.

### Alkyl Halide Deposition Inhibitors

The alkyl halide deposition inhibitors that can be used in any of the methods provided herein include alkyl fluorides, alkyl chlorides, alkyl bromides, and alkyl iodides, which may include one or more halogen atoms. Primary alkyl halides, secondary alkyl halides, and tertiary alkylhalides can be used. Examples of primary alkyl halides include methyl fluoride, methyl chloride, methyl bromide, methyl iodide, ethyl fluoride, ethyl chloride, ethyl bromide, ethyl iodide, 1-fluoropropane, 1-chloropropane, 1-bromopropane, and 1-iodopropane, 1-fluorobutane, 1-chlorobutane, 1-bromobutane, and 1-iodobutane. Examples of secondary alkyl halides include 2-fluoropropane, 2-chloropropane, 2-bromopropane, 2-iodopropane, 2-fluorobutane, 2-chlorobutane, 2-bromobutane, and 2-iodobutane. In some embodiments tertiary alkyl halides are preferred. Examples of tertiary alkyl halides include t-butyl fluoride (also known as 2-fluoro-2-methylpropane), t-butyl chloride (also known as 2-chloro-2-methylpropane), t-butyl bromide (also known as 2-bromo-2-methylpropane), and t-butyl iodide (also known as 2-bromo-2-methylpropane).

In some embodiments, alkyl halides having formula:

Hal-C(R′)₂—CH(R″)₂
are used, where Hal is a halogen, each R′ is independently selected from hydrogen and an alkyl, and each R″ is independently selected from hydrogen and an alkyl. In some embodiments both R″ groups are hydrogens. Examples of such alkyl halides include t-butyl chloride, 2-chloro-2-methylbutane, 2-chloro-2-methylpentane, and 2-chloro-2-methylhexane. These alkyl halides are particularly suitable in some embodiments, because they are amenable to hydrogen halide elimination and formation of products containing double bonds, and may lead to more efficient surface modification and inhibition of metal nucleation.

### Metal Precursors

Provided methods can use a variety of metal precursors for deposition of metals in accordance with embodiments provided herein. The precursors are selected such that they can be delivered to a process chamber in a gaseous (e.g., vapor) form, either alone or with an inert carrier gas. For example, an inert gas flowing over a solid or liquid precursor can deliver the precursor to the process chamber. Examples of metals that can be deposited using gas phase deposition, e.g., ALD and CVD deposition include molybdenum, tungsten, cobalt and ruthenium.

### Molybdenum Precursors

Generally, molybdenum-containing precursors can include molybdenum in a wide range of oxidation states ranging from 0 to +6. In some embodiments, molybdenum compounds with molybdenum in low oxidation states +3, +4 and +5 are preferred. Provided methods are particularly useful for depositing molybdenum-containing materials from halogen-containing molybdenum-containing compounds, because silicon-containing reactants can assist in halogen scavenging, but halogen-free molybdenum-containing precursors can be used as well. Suitable molybdenum-containing precursors include molybdenum halides and oxyhalides, such as fluorides, chlorides, bromides, oxyfluorides, oxychlorides, and oxybromides where molybdenum may be in any of the oxidation states from +2 to +6.

In order to maintain appropriate volatility, in many embodiments discussed herein, the precursors having molecular weights of less than about 450 g/mol, such as less than about 400 g/mol are selected.

In some embodiments the molybdenum containing precursor has a formula MoXₙYₘ, wherein X is a chalcogen (e.g., oxygen or sulfur), Y is a halogen (e.g., fluorine, chlorine, bromine, or iodine), n is 0, 1, or 2 and m is 2, 3, 4, 5, or 6. Examples of halogen-containing molybdenum-containing precursors include without limitation MoCl₅, Mo₂Cl₁₀, MoO₂Cl₂, and MoOCl₄. Another example of a halogen-containing molybdenum-containing precursor is MoF₆.

In some embodiments molybdenum-containing precursors includes carbonyl ligands. In some embodiments organometallic molybdenum precursors, such as halogen-free organometallic molybdenum precursors are used. An example of a halogen-free organometallic molybdenum precursor is bis(ethylbenzene)molybdenum.

### Halide-Containing Heteroleptic Molybdenum Compounds

In one aspect, halide-containing heteroleptic molybdenum compounds are used as precursors for deposition of molybdenum-containing films, such as for deposition of molybdenum metal. In one embodiment, the precursor is a compound that includes molybdenum, at least one halide forming a bond with molybdenum, and at least one organic ligand having any of the N, O, and S elements, where an atom of any of these elements forms a bond with molybdenum. Examples of suitable organic ligands that provide nitrogen or oxygen bonding include amidinates, amidates, iminopyrrolidinates, diazadienes, beta-imino amides, alpha-imino alkoxides, beta-amino alkoxides, beta-diketiminates, beta-ketoiminates, beta-diketonates, amines, and pyrazolates. Examples of suitable organic ligands that provide sulfur bonding include thioethers, thiolates, dithiolenes, dithiolates, and α-imino thiolenes. These ligands may be substituted or unsubstituted. In some embodiments, these ligands include one or more substituents independently selected from the group consisting of H, alkyl, fluoroalkyl, alkylsilyl, alkylamino, and alkoxy substituents. The organic ligands can be neutral or anionic (e.g., monoanionic or dianionic), and molybdenum can be in a variety of oxidation states, such as +1, +2, +3, +4, +5, and +6.

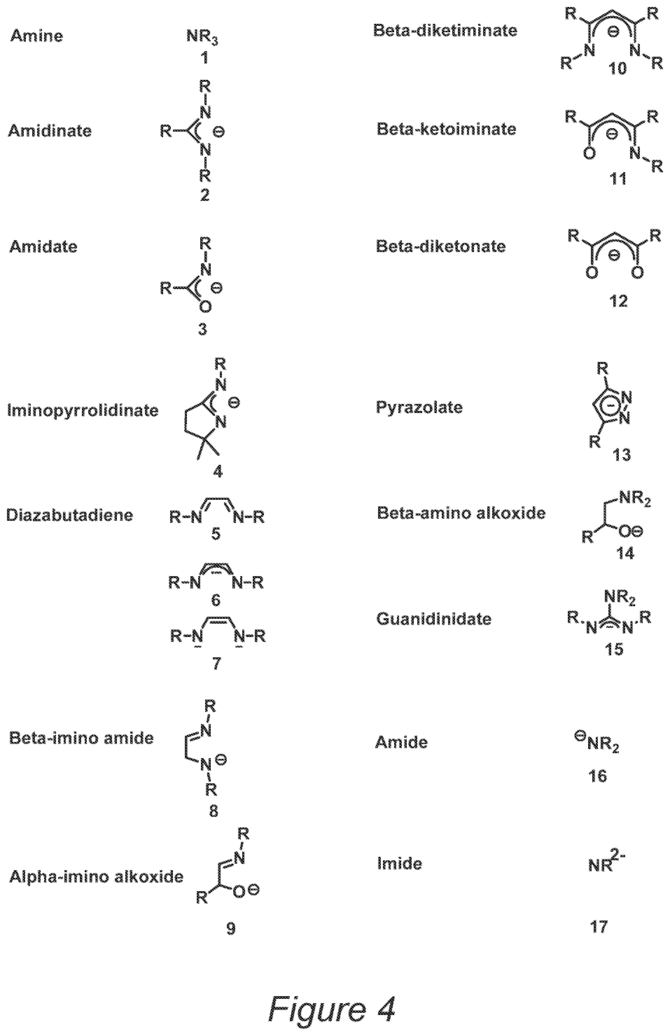

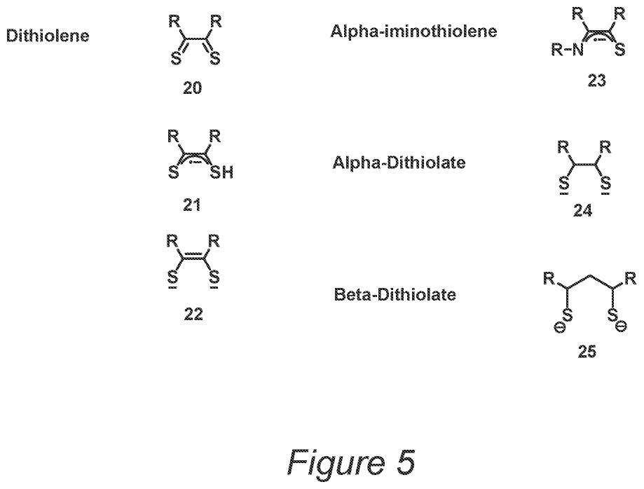

Structures of exemplary suitable N and/or O containing organic ligands 1-17 are shown in FIG. 4, and structures of exemplary suitable S-containing organic ligands 18-26 are shown in FIG. 5, where each R is independently selected from H, alkyl, fluoroalkyl, alkylsilyl, alkylamino, and alkoxy. In some embodiments, each R is independently selected from H, alkyl, and fluoroalkyl. In some embodiments each R is independently selected from H, methyl, ethyl, n-propyl, isopropyl, isobutyl, n-butyl, sec-butyl, t-butyl, pentyl, hexyl, cyclopropyl, cyclobutyl, cyclopentyl, cyclohexyl, cyclopropylmethyl, cyclopropylethyl, cyclopropylpropyl, cyclobutylmethyl, and cyclobutylethyl. In some embodiments each R is an independently selected alkyl. In some embodiments ligands with branched alkyl substituents, such as isopropyl, and isobutyl are preferred, because such ligands provide more volatile molybdenum precursors.

In some embodiments, at least one organic ligand in the precursor is an amine. Suitable amines include unidentate amines (e.g., monoalkylamines, dialkylamines), bidentate amines (e.g., unsubstituted or N-alkyl substituted ethylenediamines), and amines of higher denticities (e.g., substituted or unsubstituted diethylenetriamine). An example of a monodentate amine is amine 1, shown in FIG. 1, where at least one R is an alkyl or fluoroalkyl, and each R is independently selected from the group consisting of H, alkyl, and fluoroalkyl. In some embodiments at least one R is an alkyl, and each R is independently selected from H, and an alkyl. In some embodiments, the at least one organic ligand is an amide, such as a monoanionic amide 16, wherein at least one R is an alkyl or fluoroalkyl, and each R is independently selected from H, alkyl, and a fluoroalkyl. In some embodiments, the at least one organic ligand is an imide, such as a dianionic imide 17, wherein R is an alkyl or fluoroalkyl. While in general imide-containing precursors can be used for deposition of a variety of molybdenum-containing films (including molybdenum metal), in some embodiments they are more preferred for deposition of molybdenum nitride and molybdenum carbonitride, as they form strong molybdenum-nitrogen bonds, and can serve as sources of nitrogen for the resulting film. In some embodiments, at least one organic ligand in the precursor is an amidinate. An example of an amidinate is an amidinate 2 shown in FIG. 4, where each R is independently selected from H, alkyl, and fluoroalkyl. Amidinate 2 is a monoanionic ligand that can form two molybdenum-nitrogen bonds, serving as a bidentate ligand.

In some embodiments, at least one organic ligand in the precursor is an amidate. An example of an amidate is an amidate 3 shown in FIG. 2, where each R is independently selected from H, alkyl, and fluoroalkyl. Amidate 3 is a monoanionic ligand that can form one molybdenum-nitrogen, and one molybdenum-oxygen bond, serving as a bidentate ligand.

In some embodiments, at least one organic ligand in the precursor is a diazadiene. Examples of diazadienes are 1,4-diazabuta-1,3-dienes (DAD) 5, 6, and 7, where each R is independently selected from H, alkyl, and fluoroalkyl. An interesting property of this ligand is that it can exist in neutral form 5, monoanionic radical form 6, and dianionic form 7. Due to redox activity of monoanionic (radical) form 6, it can be relatively easily removed during deposition making complexes of DAD 6 particularly useful for deposition of molybdenum metal and high purity molybdenum metal. DAD ligands 5, 6, and 7 can serve as bidentate ligands, each forming two molybdenum-nitrogen bonds. In some embodiments the molybdenum precursor includes DAD ligand 5, 6, or 7 as an organic ligand, where each R is independently selected from methyl, ethyl, propyl, isopropyl, n-butyl, isobutyl, sec-butyl and t-butyl.

In some embodiments, the at least one organic precursor is an iminopyrrolidinate (such as an iminopyrrolidinate 4, where each R is independently selected from H, alkyl, and fluoroalkyl), a beta-imino amide (such as beta-imino amide 8, where each R is independently selected from H, alkyl, and fluoroalkyl), an alpha-imino alkoxide (such as an alpha-imino alkoxide 9, where each R is independently selected from H, alkyl, and fluoroalkyl), a beta-diketiminate (such as an beta-diketiminate 10, where each R is independently selected from H, alkyl, and fluoroalkyl), a beta-ketoiminate (such as beta-ketoiminate 11, where each R is independently selected from H, alkyl, and fluoroalkyl), a beta-diketonate 12 (such as beta-diketonate 12, where each R is independently selected from H, alkyl, and fluoroalkyl), a pyrazolate (such as pyrazolate 13, where each R is independently selected from H, alkyl, and fluoroalkyl), a beta-aminoalkoxide (such as beta-aminoalkoxide 14, where each R is independently selected from H, alkyl, and fluoroalkyl), or a guadinidate 15 (such as guadinidate 15, where each R is independently selected from H, alkyl, and fluoroalkyl). These are monoanionic ligands that are capable of binding to molybdenum in bidentate manner.

In some embodiments, the at least one organic precursor is a sulfur containing ligand that is capable of forming molybdenum-sulfur bond. In some embodiments the at least one organic ligand in the precursor is a thioether. The term “thioether” is used herein broadly to include to include both unidentate and multidentate (e.g. bidentate ot tridentate) thioethers, as well as ligands that contain both thioether and thiolate (or other) moieties. An example of a unidentate thioether is dialkylsulfide R₂S, where each R is an alkyl, such as dimethylsulfide, diethylsulfide, diisobutyl sulfide, and the like. An example of a multidentate thioether ligand that also includes thiolate moieties is (SCH₂CH₂SCH₂CH₂S)²⁻ An example of a monodentate thioether is thioether 18, shown in FIG. 5, where each R is independently selected from the group consisting of alkyl, and fluoroalkyl. In some embodiments each R is independently selected from the group consisting of methyl, ethyl, n-propyl, isopropyl, n-butyl, isobutyl, sec-butyl, and t-butyl. In some embodiments, the at least one organic ligand is a thiolate, such as a monoanionic thiolate 19, wherein R is an alkyl or fluoroalkyl. For example, R can be methyl, ethyl, n-propyl, isopropyl, n-butyl, sec-butyl, isobutyl, or t-butyl. In some embodiments the thiolate is a dithiolate, such as dianionic alpha-dithiolate 24, (where each R is independently selected from H, alkyl, and fluoroalkyl) or dianionic beta-dithiolate 25 (where each R is independently selected from H, alkyl, and fluoroalkyl). Dithiolates are capable of forming two molybdenum-sulfur bonds with molybdenum.

In some embodiments, the at least one organic ligand in the precursor is a dithiolene. Examples of dithiolenes are structures 20, 21, and 22, where each R is independently selected from H, alkyl, and fluoroalkyl. This ligand (similarly to DAD) can exist in a neutral form 20, monoanionic radical form 21, and dianionic form 22. Due to redox activity of the monoanionic radical form 21, it can be relatively easily removed during deposition and reduction of molybdenum precursor, making complexes of dithiolene 21 particularly useful for deposition of molybdenum metal and high purity molybdenum metal. Dithiolene ligands 20, 21, and 22 can serve as bidentate ligands, each capable of forming two molybdenum-sulfur bonds. In some embodiments the molybdenum precursor includes dithiolene ligand 20, 21, and/or 22 as an organic ligand, where each R is independently selected from methyl, ethyl, propyl, isopropyl, n-butyl, sec-butyl, isobutyl, and t-butyl.

In some embodiments, the at least one organic ligand in the precursor is an alpha-iminothiolene, such as structure 23, where each R is independently selected from H, alkyl, and fluoroalkyl. In some embodiments each R substituent at the carbon atoms is independently selected from H, alkyl, fluoroalkyl, alkylsilyl, alkylamino, and alkoxy substituents, while R substituent at the nitrogen is independently selected from an alkyl and fluoroalkyl. In some embodiments R substituent at the nitrogen is independently selected from methyl, ethyl, propyl, isopropyl, n-butyl, sec-butyl, isobutyl and t-butyl. This ligand (similarly to DAD, and dithiolene) has a monoanionic radical form, as shown in structure 23, is redox-active, and easily removable during reduction processes.

In some embodiments the precursor is a compound having a formula Mo(X)ₘ(L)ₙ, where m is selected from 1-4, n is selected from 1-3, each X is a halide independently selected from F, Cl, Br, and I and each L is an organic ligand as described above, e.g., a ligand independently selected from amidinates, amidates, iminopyrrolidinates, diazadienes, beta-imino amides, alpha-imino alkoxides, beta-amino alkoxides, beta-diketiminates, beta-ketoiminates, beta-diketonates, amines, and pyrazolates, thioethers, thiolates, dithiolenes, dithiolates, and α-imino thiolenes. In some embodiments in the named ligands each R is independently selected from H, alkyl, and fluoroalkyl.

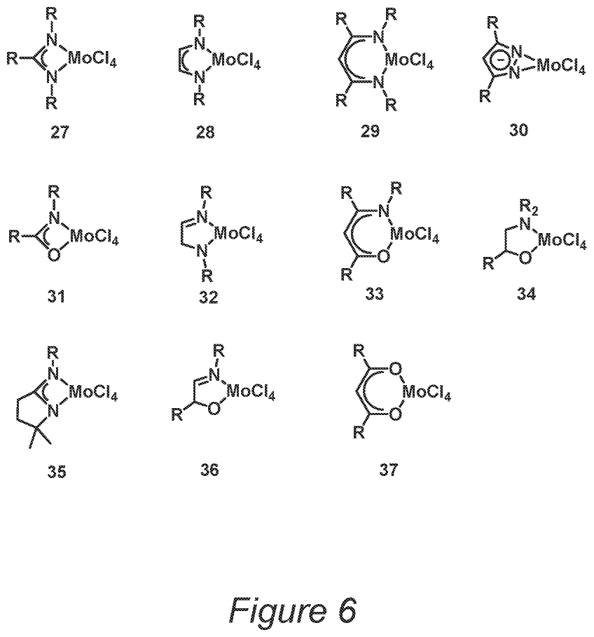

In some embodiments L is a bidentate ligand. Examples of suitable molybdenum-containing precursors of formula Mo(L)Cl₄, that utilize bidentate ligands are shown in FIG. 6. These are Mo(V) compounds and include an amidinate molybdenum complex 27, a DAD complex 28, a beta-diketiminate complex 29, a pyrazolate complex 30, an amidate complex 31, a beta-imino amide complex 32, a beta-ketoiminate complex 33, a beta-amino alkoxide complex 34, an iminopyrrolidinate complex 35, an alpha-imino alkoxide complex 36, and a beta-diketonate complex 37.

The heteroleptic complexes with molybdenum-halide bonds and organic ligands described herein can be synthesized using a reaction of molybdenum halide starting materials with the compounds comprising organic ligands in neutral or anionic form. For example, molybdenum(V) precursors may be prepared using MoCl₅ as a starting material. Mo(III) precursors may be prepared using MoX₃(THF)₃ as a starting material, where X is selected from chloride, bromide, and iodide, and THF is tetrahydrofuran. The starting materials can be treated with the ligand in a neutral or anionic form (e.g. a salt, such as lithium or sodium salt), to form the heteroleptic complexes described herein.

The heteroleptic molybdenum compounds containing molybdenum-halide bonds and organic ligands described herein can advantageously provide high purity molybdenum metal in CVD-type and ALD-type deposition methods provided herein. Further, the use of these compounds can be associated with reduced etching of the substrate materials as compared with conventional homoleptic molybdenum halides. These advantages are described for illustration purposes and do not limit the use of these compounds solely to molybdenum metal deposition or to deposition on etching-sensitive substrates.

In some embodiments, when deposition is conducted on fluorine-sensitive materials (e.g., silicon-containing materials) the precursors are selected to be fluorine free, e.g., include any of the Cl, Br, and I as the halides in the complex. Further, the use of compounds with fluoroalkyl substituents may be avoided in these embodiments.

### Sulfur-Containing Molybdenum Compounds

In one aspect, sulfur-containing molybdenum compounds are used as molybdenum-containing precursors for deposition of molybdenum-containing films, such as for deposition of molybdenum metal and molybdenum silicide. In some embodiments, the molybdenum compounds include molybdenum, and at least one sulfur-containing ligand providing molybdenum-sulfur bonding. Molybdenum precursors which are based on sulfur-containing ligands can be used to deposit molybdenum-containing films which are substantially free of impurities due to the ease of removal of sulfur impurities compared to oxygen, carbon, and nitrogen impurities. In some embodiments, the molybdenum compounds do not include molybdenum-carbon bonds and/or do not include molybdenum-oxygen double bonds. In some embodiments the molybdenum compounds do not include molybdenum-nitrogen double bonds. In some embodiments in the provided molybdenum precursors molybdenum forms bonds only with sulfur atoms.

Examples of suitable sulfur-containing ligands that provide sulfur bonding include thioethers, thiolates, dithiolenes, dithiolates, thiocarbamates, and α-imino thiolenes. The ligands can include one or more substituents independently selected from the group consisting of H, alkyl, fluoroalkyl, alkylsilyl, alkylamino, and alkoxy substituents. The ligands can be neutral or anionic (e.g., monoanionic or dianionic), and molybdenum can be in a variety of oxidation states, such as 0, +1, +2, +3, +4, +5, and +6.

In some embodiments the sulfur-containing ligands are ligands 18-25 shown in FIG. 5, where R substituents are as previously described. Examples of suitable molybdenum precursors include molybdenum thiolates Mo(SR)₄, wherein R is an alkyl, e.g., methyl, ethyl propyl, butyl.

In one specific example, the precursor is tetrakis(tert-butylthiolato)molybdenum(IV): Mo(SR)₄, wherein R is t-butyl. Another example of suitable molybdenum precursors are molybdenum thiocarbamates, such as tetrakis(diethyldithiocarbamato)molybdenum(IV):

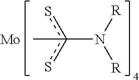

where each R is independently selected from alkyl (e.g., ethyl, methyl, propyl, butyl), and fluoroalkyl (e.g., CF₃). In one specific example the precursor is tetrakis(diethyldithiocarbamato)molybdenum(IV).

In some embodiments dithiolene complexes of molybdenum are provided, where dithiolene may be in any of a neutral form 20, anion-radical form 21, and dianionic form 22, where each R is independently H, alkyl or fluoroalkyl.

Dithiolene complexes are redox-active and can support molybdenum in a variety of oxidation states. Redox reactions of dithiolene ligands 20, 21, and 22 are shown in Equation 1:

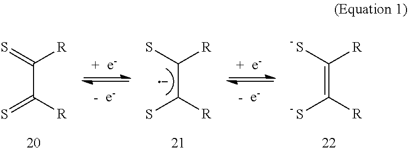

In one implementation, the precursor is Mo(21)₃, where each R in 21 is independently selected from H, alkyl, and fluoroalkyl. For example, R may be methyl, ethyl, CF₃, etc. This is a homoleptic Mo(III) compound containing exclusively molybdenum-sulfur bonds.

In some embodiments, the ligands may provide nitrogen bonding in addition to sulfur bonding. One example of such ligand is alpha-iminothiolene 23, which is a redox-active radical anion ligand that can exhibit behavior similar to that of thiolenes. In some embodiments the precursor is Mo(III) compound Mo(23)₃, where each R in compound 23 is independently selected from H, alkyl, and fluoroalkyl.

In some embodiments, the precursor is MoLₙ compound, where n is from 2 to 6, and L is a sulfur-containing ligand, such as any of the sulfur-containing ligands described herein. In some embodiments each L is the same sulfur-containing ligand. In other embodiments the precursor may include different sulfur containing ligands L. Examples of precursors include Mo(19)₂, Mo(19)₃, Mo(19)₄, Mo(19)₅, Mo(19)₆, Mo(19)₂(18)₂, Mo(19)₃(18), Mo(19)₄(18)₂, Mo(21)₃, Mo(20)(21)₂, Mo(22)₃, Mo(21)(22)₂, Mo(20)(22)₂, Mo(23)₃, Mo(24)₃, Mo(25)₃. The sulfur-containing molybdenum compounds described herein can be synthesized using a reaction of molybdenum halide starting materials with the compounds comprising organic sulfur-containing ligands in neutral or anionic form. For example, molybdenum(V) precursors may be prepared using MoCl₅ as a starting material. Mo(III) or Mo(IV) precursors may be prepared using corresponding halides or MoX₃(L)₃ or MoX₄(L)₂ as a starting material, where X is selected from chloride, bromide, and iodide, and L is a neutral Lewis base such as tetrahydrofuran or diethyl ether. The starting materials can be treated with the desired sulfur-containing ligand in a neutral or anionic form (e.g. a salt, such as lithium or sodium salt), to form the sulfur-containing complexes described herein.

In one example, Mo(IV) thiolato complexes are prepared by reacting molybdenum tetrachloride with lithium thiolates. For example MoCl₄ can be reacted with t-BuSLi in 1,2-dimethoxythane solvent to form Mo(t-BuS)₄ compound.

α-Iminothiolene ligands can be prepared from the corresponding α-iminoketone by thionation using a suitable reagent such as Lawesson's reagent. The radical anionic form of the α-iminothiolene can be prepared subsequently by treatment with an alkali metal, such as lithium. The resulting ligands and ligand salts can be reacted with molybdenum halides to form α-iminothiolene-containing molybdenum compounds.

Molybdenum complexes can also be prepared using a zero valent starting material such as molybdenum hexacarbonyl. The starting material can be treated with a neutral ligand, such as a thioether (dialkylsulfide), to induce redox neutral ligand exchange. The zero valent starting material can also be treated with a ligand precursor, such as bis(diethylthiocarbamoyl)disulfide or bis(trifluoromethyl)-1,2-dithiete, to induce oxidative addition and form the sulfur-containing complexes described herein.

The reactions may be conducted in a variety of non-protic solvents. For example the reaction may be conducted in an ether solvent, such as tetrahydrofuran, 2-methyltetrahydrofuran, diethyl ether, methyl-tert-butyl ether, 1,2-dimethoxyethane, in a hydrocarbon solvent such as toluene, benzene, heptane, hexane, pentane, or in a halocarbon solvent such as chlorobenzene, dichlorobenzene, fluorobenzene, difluorobenzene, dichloromethane, chloroform, etc. The reactions can be conducted in a wide temperature range depending on the boiling point of the solvent and on solubility of the products. In some embodiments, the starting materials, reaction intermediates, and the desired products are unstable toward moisture and oxygen. Accordingly, the reaction process should be conducted using anhydrous and air-free conditions using a protective inert gas, such as nitrogen or argon.

### 1,4-Diazabutadiene (DAD) Containing Precursors

In another aspect, DAD-containing molybdenum-containing precursors are provided. DAD can bind to molybdenum in its neutral form 5, in its radical-anionic form 6, and in its dianionic form 7. In some embodiments, homoleptic DAD complexes are provided of formula Mo(DAD)m, where m is from 1 to 3, and each DAD is independently selected from neutral DAD 5, radical-anionic DAD 6, and dianionic DAD 7. The oxidation state of molybdenum in these complexes can range from 0 to +6. Non-limiting examples of suitable homoleptic DAD complexes include tris-DAD Mo(III) precursor Mo(6)₃, bis-DAD Mo(IV) precursor Mo(7)₂, bis-DAD Mo(III) precursor Mo(6)(7), and bis-DAD Mo(II) precursor Mo(6)₂.

In some embodiments homoleptic DAD complexes are prepared using a reaction between molybdenum halide and a source of DAD ligand in the required electronic configuration. For example, tris-DAD Mo(III) precursor Mo(6)₃ can be synthesized by reacting MoCl₃ with three equivalents of the radical anion form of the DAD ligand, which can be prepared from the neutral form of the DAD ligand by treatment with an alkali metal, such as lithium, in a solvent, such as THF, as shown in Equation 2

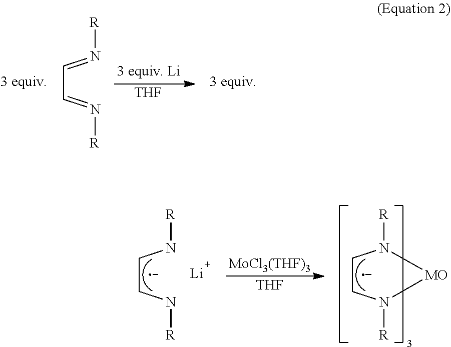

In some embodiments, heteroleptic DAD-containing molybdenum compounds are provided. In some implementations the precursor includes molybdenum, at least one DAD ligand bound to molybdenum, and at least one second ligand, wherein the DAD may be neutral DAD 6, radical anionic DAD 7, or dianionic DAD 8, and the second ligand is independently selected from anionic ligands and neutral ligands. In some embodiments the precursor does not contain CO ligands as the only second ligands. In some embodiments the precursor is Mo(DAD)ₘ(L)ₙ(X)ₚ, where L is a neutral Lewis base ligand and each L is independently selected from CO, an amine, a phosphine, a thioether, a nitrile, and an isonitrile, and X is an anionic ligand, and each X is independently selected from a halide, an alkyl, an allyl, and a cyclopentadienyl, and m is 1-3, n is 0-4, and p is 0-4. Nitriles are RCN compounds, where R is an alkyl. Isonitriles are RNC compounds, where R is an alkyl. Other suitable anionic ligands include alkoxides, amides, imides, and any other anionic ligands that include a donor atom chosen from C, N, O, B, S, Si, Al, and P.

Examples of heteroleptic DAD-containing precursors include without limitation Mo(7)₂(RCN)Cl, MO(7)₂(RNC)Cl, Mo(8)(CO)₃, Mo(6)(13)Cl, Mo(6)(18)Cl₂, Mo(6)₂Cl, Mo(6)₂(14), Mo(6)₂(19), Mo(6)₂(24).

Heteroleptic DAD-containing precursors can be prepared by sequential salt metathesis reactions in one pot or using multiple steps. Molybdenum halide starting materials such as Mo(V), Mo(IV), or Mo(III) halides can be treated with anionic forms of a DAD ligand or other anionic ligands. Neutral Lewis base ligands can be exchanged using thermal treatment or photoexcitation.

Heteroleptic DAD-containing precursors can also be prepared using a zero valent molybdenum starting material, such as molybdenum hexacarbonyl, which can undergo oxidative addition with redox active ligands, such as DAD ligands.

In some embodiments, the precursors containing radical anionic DAD ligand 8 are particularly preferred for deposition of molybdenum metal and high purity molybdenum metal. In the radical anionic form 7, the DAD ligand is electronically coupled to vacant molybdenum d-orbitals and is believed to serve as a source of electrons which reduce the molybdenum ions to the zerovalent metallic state. After ligand-to-metal electron transfer, the volatile, neutral DAD ligand 6 can be purged away from the molybdenum metal growth surface. Since the DAD ligand can be removed intact from the growth surface, incorporation of impurity elements such as C and N are reduced when using DAD precursors as compared to other metalorganic precursors. Therefore, molybdenum precursors containing radical anionic DAD ligands can be used for depositing high purity molybdenum metal at low temperatures.

### Di-Molybdenum Precursors

In another aspect, precursors for deposition of molybdenum-containing films are di-molybdenum compounds containing a molybdenum-molybdenum bond (e.g., a multiple molybdenum-molybdenum bond, such as a double bond, or any multiple bond with a bond order of 2-5). Such precursors are particularly useful for deposition of molybdenum metal and high purity molybdenum metal because it is easier to reduce such compounds to metallic molybdenum than many mononuclear molybdenum compounds.

In some embodiments, a precursor for deposition of molybdenum-containing films is provided, wherein the precursor is Mo₂Lₙ, wherein each L is independently selected from amidate, amidinate, and guanidinate ligands, n is 2-5, and where the precursor includes a multiple molybdenum-molybdenum bond. In some embodiments each L is independently selected from an amidinate ligand 2, amidate ligand 3, and a guanidinate ligand 15, wherein each R in the amidinate, amidate, and guanidinate is independently selected from H, alkyl, fluoroalkyl, alkylsilyl, alkylamino, and alkoxy substituents. In some embodiments each R is independently selected from H, alkyl, and fluoroalkyl. In some embodiments each L is an amidinate and the precursor has a formula Mo₂(L)₃ or Mo₂(L)₄. In some embodiments each L is an amidinate and the precursor has a formula Mo₂(L)₃ or Mo₂(L)₄. In some embodiments each L is a guanidinate and the precursor has a formula Mo₂(L)₃ or Mo₂(L)₄. In these complexes molybdenum has a low oxidation state 2+(in Mo₂(L)₃) and 3+ in (Mo₂(L)₄) making these complexes particularly suitable for facile reduction to molybdenum metal.

One exemplary structure of an amidate paddlewheel di-Mo (II) precursor having a quadruple molybdenum-molybdenum bond is shown by structure 38:

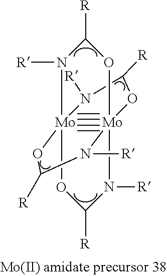

In some embodiments each of R and R′ is independently selected from alkyls, such as methyl, ethyl, isopropyl, and t-butyl. In some embodiments one, two, three or four amidate ligands in 38 may be substituted by amidinate or guanidinidate ligands.

Di-molybdenum precursors described herein can be synthesized using dimolybdenum tetraacetate as a starting material by treatment with a ligand salt such as lithium amidate.

### Cobalt Precursors

Cobalt metal can be deposited using a variety of cobalt precursors, where cobalt may be in +1, +2 or +3 oxidation states. Examples of cobalt precursors include cobalt acetate, cobalt acetylacetonates (e.g., cobalt (III) bis(acetylacetonate)), cobalt amidinates (e.g., bis(N-t-butyl-N′-ethylpropanimidamidato)cobalt(II),) cobaltocene, and carbonyl-containing cobalt precursors (e.g., cobalt tricarbonyl nitrosyl, and cyclopentadienylcobalt dicarbonyl). An example of a halogen-containing cobalt precursor is CoCl₂(TMEDA), where TMEDA is N,N,N,N′-tetramethylethylenediamine.

### Ruthenium Precursors

Ruthenium metal can be deposited, for example, using vaporizable ruthenium precursors, such as bis(ethylcyclopentadienyl)ruthenium(II), bis(pentamethylcyclopentadienyl)ruthenium, ruthenocene, and cyclopentadienyl-propyleyclopentadienylruthenium(II).

### Tungsten Precursors

Tungsten can be deposited using a variety of volatile precursors. In some embodiments halogen-containing tungsten precursors, such as WHalₓ, where Hal is a halogen (e.g., F, Cl, Br, and/or I) and x is from 2 to 6, are used. In some embodiments tungsten chloride is used. Tungsten chloride includes tungsten pentachloride (WCl₅), tungsten hexachloride (WCl₆), tungsten tetrachloride (WCl₄), tungsten dichloride (WCl₂), and mixtures thereof. In other examples tungsten fluoride, such as tungsten hexafluoride may be used.

### Reducing Agent

A number of reducing agents can be used for deposition of metal films provided herein. The reducing agent is selected such that it can reduce the metal precursor to metal or to assist in this reduction. Examples of suitable reactants for forming molybdenum metal include hydrogen (H₂), ammonia (NH₃), hydrazine (N₂H₄), an amine, diborane (B₂H₆), silane (SiH₄), disilane (Si₂H₆), an alcohol, hydrogen sulfide (H₂S), or a thiol. In some embodiments the reducing agent is hydrogen (H₂).

### Apparatus

The deposition methods described herein can be carried out in a variety of apparatuses. A suitable apparatus includes a processing chamber having one or more inlets for introduction of reactants, a substrate holder in the process chamber configured to hold the substrate in place during deposition, and, optionally, a plasma generating mechanism configured for generating a plasma in a process gas. Generally, the methods provided herein do not require activation of reactants by plasma, and can be conducted in an absence of plasma treatments. The apparatus may include a controller having program instructions configured to cause performance of any of the method steps described herein. The deposition methods described herein may be carried out in corresponding ALD and CVD apparatuses available from Lam Research Corp. of Fremont, CA, such as Halo, Altus®, Vector®, and Striker® tools.

For example, in some embodiments the apparatus includes a controller having program instructions that include instructions for: causing exposure of a semiconductor substrate having a recessed feature to an alkyl halide inhibitor, where the alkyl halide inhibitor modifies a surface of a substrate to make it more resistant to metal deposition; causing exposure of the semiconductor substrate to a metal precursor and a reducing agent to deposit a layer of metal. The controller may include program instructions for causing any of the methods described herein.

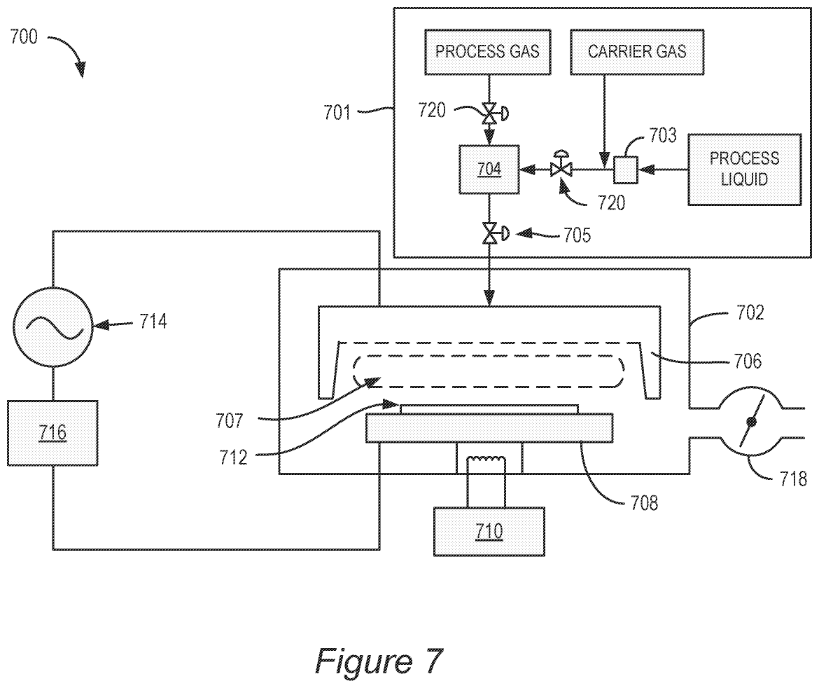

An example of a deposition apparatus suitable for depositing metal films using provided methods is shown in FIG. 7. FIG. 7 schematically shows an embodiment of a process station 700 that may be used to deposit material using atomic layer deposition (ALD) and/or chemical vapor deposition (CVD), either of which may be plasma enhanced. For simplicity, the process station 700 is depicted as a standalone process station having a process chamber body 702 for maintaining a low-pressure environment. However, it will be appreciated that a plurality of process stations 700 may be included in a common process tool environment. Further, it will be appreciated that, in some embodiments, one or more hardware parameters of process station 700, including those discussed in detail below, may be adjusted programmatically by one or more computer controllers.

Process station 700 fluidly communicates with reactant delivery system 701 for delivering process gases to a distribution showerhead 706. Reactant delivery system 701 includes a mixing vessel 704 for blending and/or conditioning process gases for delivery to showerhead 706. One or more mixing vessel inlet valves 720 may control introduction of process gases to mixing vessel 704. Similarly, a showerhead inlet valve 705 may control introduction of process gasses to the showerhead 706.

Some metal precursors may be stored in solid or liquid form prior to vaporization and subsequent delivery to the process station. For example, the embodiment of FIG. 7 includes a vaporization point 703 for vaporizing solid reactant to be supplied to mixing vessel 704. In some embodiments, vaporization point 703 may be a heated vaporizer. In some embodiments a flow of an inert gas is passed over the heated solid metal precursor, or bubbled through the heated liquid metal precursor, under sub-atmospheric pressure, and carries the precursor vapor to the process chamber. The precursor vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 703 may be heat traced. In some examples, mixing vessel 704 may also be heat traced. In one non-limiting example, piping downstream of vaporization point 703 has an increasing temperature profile extending from approximately 100° C. to approximately 200° C. at mixing vessel 704.

Showerhead 706 distributes process gases toward substrate 712. In the embodiment shown in FIG. 7, substrate 712 is located beneath showerhead 706, and is shown resting on a pedestal 708. It will be appreciated that showerhead 706 may have any suitable shape, and may have any suitable number and arrangement of ports for distributing processes gases to substrate 712. While not explicitly shown, in some embodiments the showerhead 706 is a dual plenum showerhead that includes at least two types of conduits, where the first type of conduit is dedicated to delivery of molybdenum-containing precursor vapor, and the second type of conduit is dedicated to delivery of the second (or other) reactant. In these embodiments the molybdenum-containing precursor and the reactant are not allowed to mix in the conduits prior to entry to the process chamber, and do not share the conduits if delivered to the chamber consecutively.

In some embodiments, a microvolume 707 is located beneath showerhead 706. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 708 may be raised or lowered to expose substrate 712 to microvolume 707 and/or to vary a volume of microvolume 707. For example, in a substrate transfer phase, pedestal 708 may be lowered to allow substrate 712 to be loaded onto pedestal 708. During a deposition process phase, pedestal 708 may be raised to position substrate 712 within microvolume 707. In some embodiments, microvolume 707 may completely enclose substrate 712 as well as a portion of pedestal 708 to create a region of high flow impedance during a deposition process.

Optionally, pedestal 708 may be lowered and/or raised during portions the deposition process to modulate process pressure, reactant concentration, etc., within microvolume 707. In one scenario where process chamber body 702 remains at a base pressure during the deposition process, lowering pedestal 708 may allow microvolume 707 to be evacuated. Example ratios of microvolume to process chamber volume include, but are not limited to, volume ratios between 1:700 and 1:10. It will be appreciated that, in some embodiments, pedestal height may be adjusted programmatically by a suitable computer controller.

While the example microvolume variations described herein refer to a height-adjustable pedestal, it will be appreciated that, in some embodiments, a position of showerhead 706 may be adjusted relative to pedestal 708 to vary a volume of microvolume 707. Further, it will be appreciated that a vertical position of pedestal 708 and/or showerhead 706 may be varied by any suitable mechanism within the scope of the present disclosure. In some embodiments, pedestal 708 may include a rotational axis for rotating an orientation of substrate 712. It will be appreciated that, in some embodiments, one or more of these example adjustments may be performed programmatically by one or more suitable computer controllers.

Returning to the embodiment shown in FIG. 7, showerhead 706 and pedestal 708 electrically communicate with RF power supply 714 and matching network 716 for powering a plasma. In other embodiments apparatuses without a plasma generator are used for depositing molybdenum-containing films using provided methods. In some embodiments, the plasma energy may be controlled by controlling one or more of a process station pressure, a gas concentration, a radio frequency (RF) source power, an RF source frequency, and a plasma power pulse timing. For example, RF power supply 714 and matching network 716 may be operated at any suitable power to form a plasma having a desired composition of radical species. Likewise, RF power supply 714 may provide RF power of any suitable frequency. In some embodiments, RF power supply 714 may be configured to control high- and low-frequency RF power sources independently of one another. Example low-frequency RF frequencies may include, but are not limited to, frequencies between 50 kHz and 700 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some embodiments, pedestal 708 may be temperature controlled via heater 710. Further, in some embodiments, pressure control for deposition process station 700 may be provided by butterfly valve 718. As shown in the embodiment of FIG. 7, butterfly valve 718 throttles a vacuum provided by a downstream vacuum pump (not shown). However, in some embodiments, pressure control of process station 700 may also be adjusted by varying a flow rate of one or more gases introduced to process station 700.

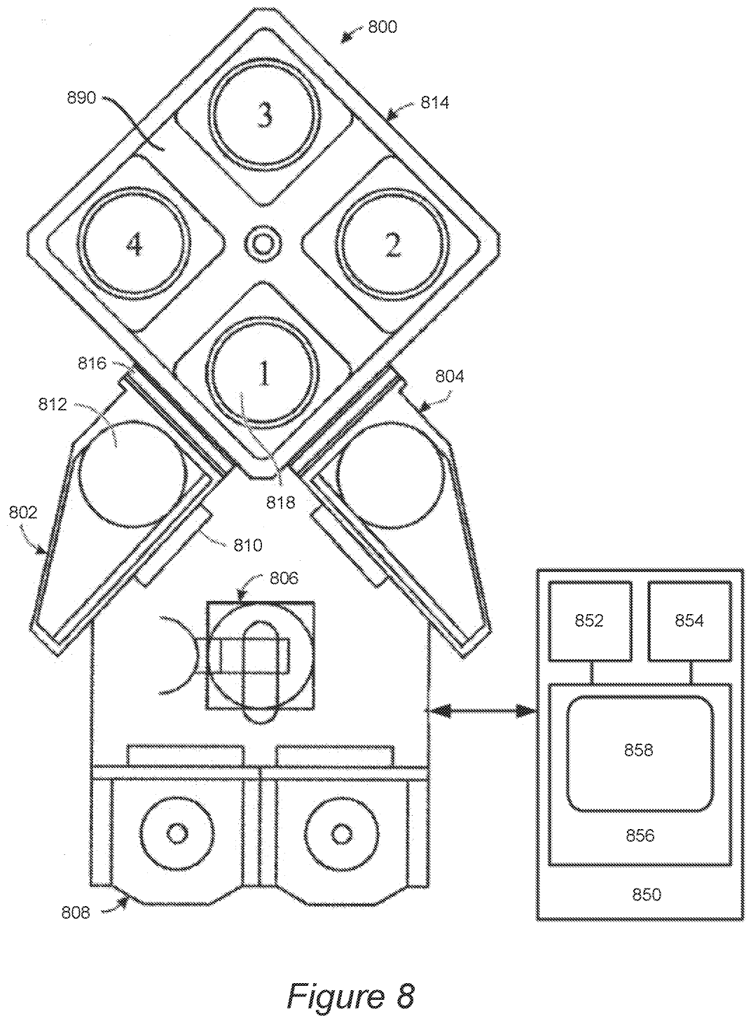

FIG. 8 shows a schematic view of an embodiment of a multi-station processing tool 800 with an inbound load lock 802 and an outbound load lock 804, either or both of which may comprise a remote plasma source. Such tool may be used for processing the substrates using the methods provided herein. A robot 806, at atmospheric pressure, is configured to move wafers from a cassette loaded through a pod 808 into inbound load lock 802 via an atmospheric port 810. A wafer is placed by the robot 806 on a pedestal 812 in the inbound load lock 802, the atmospheric port 810 is closed, and the load lock is pumped down. Where the inbound load lock 802 comprises a remote plasma source, the wafer may be exposed to a remote plasma treatment in the load lock prior to being introduced into a processing chamber 814. Further, the wafer also may be heated in the inbound load lock 802 as well, for example, to remove moisture and adsorbed gases. Next, a chamber transport port 816 to processing chamber 814 is opened, and another robot (not shown) places the wafer into the reactor on a pedestal of a first station shown in the reactor for processing. While the embodiment depicted in FIG. 8 includes load locks, it will be appreciated that, in some embodiments, direct entry of a wafer into a process station may be provided.

The depicted processing chamber 814 comprises four process stations, numbered from 1 to 4 in the embodiment shown in FIG. 8. Each station has a heated pedestal (shown at 818 for station 1), and gas line inlets. It will be appreciated that in some embodiments, each process station may have different or multiple purposes. While the depicted processing chamber 814 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 also depicts an embodiment of a wafer handling system 890 for transferring wafers within processing chamber 814. In some embodiments, wafer handling system 890 may transfer wafers between various process stations and/or between a process station and a load lock. It will be appreciated that any suitable wafer handling system may be employed. Non-limiting examples include wafer carousels and wafer handling robots. FIG. 8 also depicts an embodiment of a system controller 850 employed to control process conditions and hardware states of process tool 800. System controller 850 may include one or more memory devices 856, one or more mass storage devices 854, and one or more processors 852. Processor 852 may include a CPU or computer, analog and/or digital input/output connections, stepper motor controller boards, etc.

In some embodiments, system controller 850 controls all of the activities of process tool 800. System controller 850 executes system control software 858 stored in mass storage device 854, loaded into memory device 856, and executed on processor 852. System control software 858 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 800. System control software 858 may be configured in any suitable way. For example, various process tool component subroutines or control objects may be written to control operation of the process tool components necessary to carry out various process tool processes in accordance with the disclosed methods. System control software 858 may be coded in any suitable computer readable programming language.

In some embodiments, system control software 858 may include input/output control (IOC) sequencing instructions for controlling the various parameters described above. For example, each phase of an ALD process may include one or more instructions for execution by system controller 850. The instructions for setting process conditions for an ALD process phase may be included in a corresponding ALD recipe phase. In some embodiments, the ALD recipe phases may be sequentially arranged, so that all instructions for a ALD process phase are executed concurrently with that process phase.

Other computer software and/or programs stored on mass storage device 854 and/or memory device 856 associated with system controller 850 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 818 and to control the spacing between the substrate and other parts of process tool 800.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 850. The user interface may include a display screen, graphical software displays of the apparatus and/or process conditions, and user input devices such as pointing devices, keyboards, touch screens, microphones, etc.

In some embodiments, parameters adjusted by system controller 850 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 850 from various process tool sensors. The signals for controlling the process may be output on the analog and digital output connections of process tool 800. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the Halo® product family, available from Lam Research Corp., of Fremont, California, or any of a variety of other commercially available processing systems. Two or more of the stations may perform the same functions. Similarly, two or more stations may perform different functions. Each station can be designed/configured to perform a particular function/method as desired.

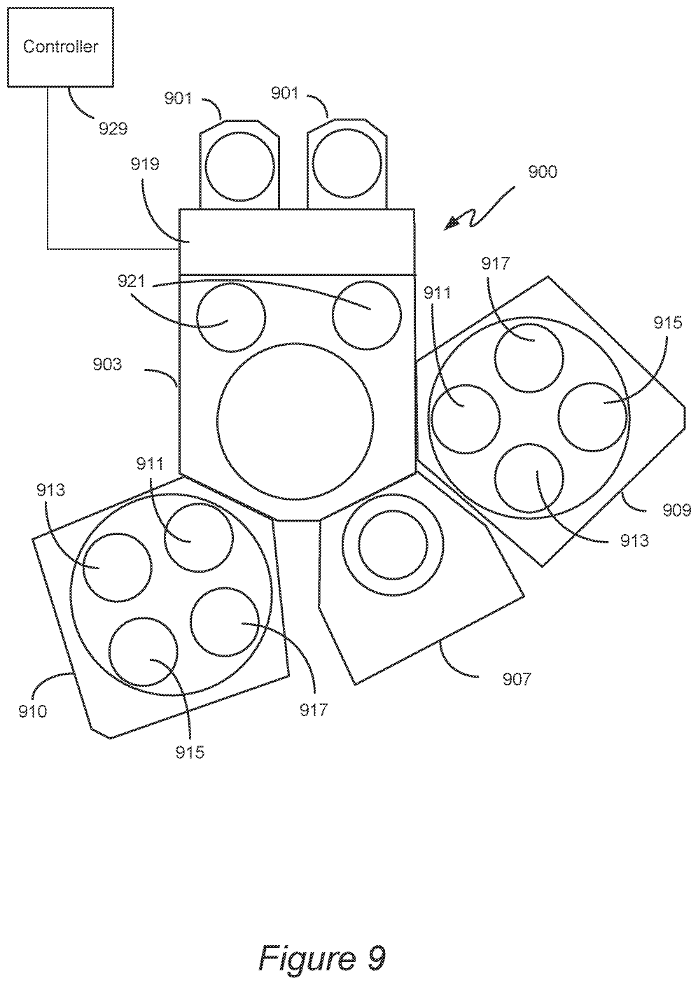

FIG. 9 is a block diagram of a processing system suitable for conducting thin film deposition processes in accordance with certain embodiments. The system 900 includes a transfer module 903. The transfer module 903 provides a clean, pressurized environment to minimize risk of contamination of substrates being processed as they are moved between various reactor modules. Mounted on the transfer module 903 are two multi-station reactors 909 and 910, each capable of performing atomic layer deposition (ALD) and/or chemical vapor deposition (CVD) according to certain embodiments. Reactors 909 and 910 may include multiple stations 911, 913, 915, and 917 that may sequentially or non-sequentially perform operations in accordance with disclosed embodiments. The stations may include a heated pedestal or substrate support, one or more gas inlets or showerhead or dispersion plate.

Also mounted on the transfer module 903 may be one or more single or multi-station modules 907 capable of performing plasma or chemical (non-plasma) pre-cleans, or any other processes described in relation to the disclosed methods. The module 907 may in some cases be used for various treatments to, for example, prepare a substrate for a deposition process. The module 907 may also be designed/configured to perform various other processes such as etching or polishing. The system 900 also includes one or more wafer source modules 901, where wafers are stored before and after processing. An atmospheric robot (not shown) in the atmospheric transfer chamber 919 may first remove wafers from the source modules 901 to loadlocks 921. A wafer transfer device (generally a robot arm unit) in the transfer module 903 moves the wafers from loadlocks 921 to and among the modules mounted on the transfer module 903.

In various embodiments, a system controller 929 is employed to control process conditions during deposition. The controller 929 will typically include one or more memory devices and one or more processors. A processor may include a CPU or computer, analog and/or digital input/output connections, stepper motor controller boards, etc.

The controller 929 may control all of the activities of the deposition apparatus. The system controller 929 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 929 may be employed in some embodiments.

Typically there will be a user interface associated with the controller 929. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the reducing agent flow, alkyl halide inhibitor flow, metal precursor flow, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 929. The signals for controlling the process are output on the analog and digital output connections of the deposition apparatus 900.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller 929 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 929, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Further Implementations

The apparatus and processes described herein may be used in conjunction with lithographic patterning tools or processes, for example, for the fabrication or manufacture of semiconductor devices, displays, LEDs, photovoltaic panels, and the like. Typically, though not necessarily, such apparatus and processes will be used or conducted together in a common fabrication facility. Lithographic patterning of a film typically comprises some or all of the following steps, each step enabled with a number of possible tools: (1) application of photoresist on a work piece, i.e., a substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or work piece by using a dry or plasma-assisted etching tool; and (6) removing the resist using a tool such as an RF or microwave plasma resist stripper.

### EXPERIMENTAL EXAMPLES

Molybdenum was deposited on TiN and W surfaces with and without alkyl halide inhibition. MoCl₅ was used as a molybdenum precursor, H₂ was used as a reducing agent, and t-butyl chloride (also known as 2-chloro-2-methylpropane) as the inhibitor. In an absence of t-butyl chloride inhibition, molybdenum was deposited on a substrate (with either TiN or W surface) be repeating deposition cycles (170 cycles), where each cycle included MoCl₅ exposure and H₂ exposure. Molybdenum was deposited to a thickness of about 120 Å on both TiN and W substrates.

In a first example with inhibition, the substrate (with either TiN or W surface) was pre-treated with t-butyl chloride followed by inhibitor-free deposition cycles (170 cycles), where each cycle included sequential exposure to MoCl₅ and H₂. Molybdenum was deposited to a thickness of about 50 Å on both TiN and W substrates.

In a second example with inhibition, molybdenum was deposited on a substrate (with either TiN or W surface) by performing 170 deposition cycles, where each cycle included sequential t-butyl chloride exposure, MoCl₅ exposure and H₂ exposure. Molybdenum was deposited to a thickness of about 70 Å on both TiN and W substrates. These examples demonstrate that t-butyl chloride effectively inhibited molybdenum deposition on both TiN and W surfaces in both pre-soak alkyl halide inhibition process and in a three-step cyclic deposition (inhibitor-assisted deposition), where each full ALD cycle includes an inhibitor exposure.

1. A method of forming a metal layer, the method comprising:
(a) providing a semiconductor substrate having a recessed feature;
(b) exposing the semiconductor substrate to a deposition inhibitor, wherein the deposition inhibitor is a halogen-containing compound, and wherein the deposition inhibitor modifies a surface of the semiconductor substrate to make the surface more resistant to metal deposition than the surface was before modification; and
(c) exposing the semiconductor substrate to a metal precursor and a reducing agent to form a metal layer at least within the recessed feature on the semiconductor substrate, wherein the metal precursor and the halogen-containing compound are different.

2. The method of claim 1, wherein the semiconductor substrate is exposed to the deposition inhibitor prior to exposure to the metal precursor.

3. (canceled)

4. The method of claim 1, wherein the halogen-containing compound is an iodine-containing compound.

5. The method of claim 1, wherein the metal layer comprises a molybdenum layer, or a cobalt layer, or a ruthenium layer, or any combination thereof.

6. The method of claim 1, wherein the halogen-containing compound is selected from the group consisting of I₂ (diiodine), HI (hydrogen iodide), CH₃I (methyl iodide), C₂H₅I (ethyl iodide), 1-iodopropane, 2-iodopropane, 1-iodobutane, sec-butyl iodide, t-butyl iodide, iodocyclopentane, iodocyclohexane, diiodomethane, 1,2-diiodoethane, 1,1-diiodopropane, 1,2-diiodopropane, 1,3-diiodopropane, 2,2-diiodopropane, 1,1-diiodobutane, 1,2-diiodobutane, 1,3-diiodobutane, 2,2-diiodobutane, 2,3-diiodobutane, 1,2-diiodo-2-methylpropane, 2,3-diiodo-2,3-dimethylbutane, 1,1,2,2-tetraiodoethane, 2,2,3,3-tetraiodobutane, 1,1,1,2,2,2-hexaiodoethane, 1,2-diiodocyclopentane, 1,2-diiodocyclohexane, iodobenzene, diiodobenzene, 2-iodopyridine, 3-iodopyridine, 4-iodopyridine, 3-iodo-1-nitrobenzene, 3-iodo-1-trifluoromethylbenzene, 4-iodoaniline, 4-iodo-1-dimethylaminobenzene, 4-iodophenol, (trimethylsilyl)methyl iodide, (trimethylsilyl)methyl diiodide, (trimethylsilyl)methyl triiodide, bis(trimethylsilyl)methyl iodide, bis(trimethylsilyl)methyl diiodide, tris(trimethylsilyl)methyl iodide, 1-(trimethylsilyl)-1-iodoethane, 1-(trimethylsilyl)-1,2-diiodoethane, 1,1-bis(trimethylsilyl)-1,2-diiodoethane, 1,2-bis(trimethylsilyl)-1,2-diiodoethane, CHI₃ (triiodomethane), CI₄ (carbon tetraiodide), 1-iodoethene, 1-iodopropene, 2-iodopropene, 1-iodo-1-butene, 1-iodo-2-butene, 2-iodo-1-butene, 2-iodo-2-butene, iodoacetylene, 3,3-dimethyl-1-iodo-but-1-yne, 1,1-diiodoethene, 1,2-diiodoethene, 1,2-diiodopropene, 1,2-diiodo-2-propene, 1,2-diiodobutene, 1,2-diiodo-2-butene, 1,2-diiodo-3-butene, 3,4-diiodocyclohexene, 4,5-diiodocyclohexadiene, 1,2-diiodoacetylene, 1,1,2,2-tetraiodoethene, SiI₄ (silicon tetraiodide), SiHI₃ (triiodosilane), SiH₂I₂ (dioiodosilane), SiH₃I (iodosilane), Si(CH₃)I₃ (methylsilyl triiodide), Si(CH₃)₂I₂ (dimethylsilyl dioiodide), Si(CH₃)₃I (trimethylsilyl iodide), Si(CH₃)HI₂ (diiodomethylsilane), Si(CH₃)₂HI (iododimethylsilane), Si(CH₃)H₂I (methyliodosilane), Si₂I₆ (hexaiododisilane), GeI₄ (germanium tetraiodide), GeHI₃ (triiodogermane), GeH₂I₂ (diiodogermane), GeH₃I (iodogermane), AlI₃ (aluminum triiodide), BI₃ (boron triiodide), TiI₄ (titanium tetraiodide), SnI₄ (tin tetraiodide), N-iodosuccinimide, 1,3-diiodo-5,5-dimethylhydantoin, N-iodophthalimide, N-iodosaccharin, 1-chloro-2-iodoethane, iodinechloride (ICl), and combinations thereof.

7. The method of claim 1, wherein the metal layer is a molybdenum layer, and the metal precursor is a molybdenum precursor.

8. The method of claim 7, wherein the molybdenum precursor comprises MoCl₅, Mo₂Cl₁₀, MoO₂Cl₂, MoOCl₄, bis(ethylbenzene)molybdenum or any combination thereof.

9. The method of claim 1, wherein the deposition inhibitor modifies a surface on a field region and near an opening of the recessed feature to a greater degree than a surface of a bottom of the recessed feature.

10. The method of claim 1, wherein the deposition inhibitor modifies the surface of the semiconductor substrate by at least one of physisorption and chemisorption.

11. The method of claim 1, wherein the deposition inhibitor modifies the surface of the semiconductor substrate by halogenating the surface of the substrate.

12. The method of claim 1, wherein the metal layer is deposited at a temperature of between about 250° C. and about 600° C. and a pressure of less than about 300 torr.

13. (canceled)

14. The method of claim 1, wherein the semiconductor substrate provided in (a) comprises exposed metal nitride, wherein the exposed metal nitride lines sidewalls of the recessed feature and a bottom of the recessed feature.

15. The method of claim 1, wherein the semiconductor substrate provided in (a) comprises exposed titanium nitride, wherein the exposed titanium nitride lines sidewalls of the recessed feature and a bottom of the recessed feature.

16. The method of claim 1, wherein the semiconductor substrate provided in (a) comprises an exposed silicon-containing dielectric and an exposed metal, wherein the exposed silicon-containing dielectric is exposed at sidewalls of the recessed feature, and the exposed metal is exposed at a bottom of the recessed feature.

17. The method of claim 1, wherein (c) comprises sequentially exposing the semiconductor substrate to the metal precursor and a reducing agent, and repeating the sequential exposure to perform at least 10 inhibitor-free deposition cycles.

18. The method of claim 1, wherein the method comprises:
(i) exposing the semiconductor substrate to the deposition inhibitor;
(ii) after (i), exposing the semiconductor substrate to the metal precursor;
(iii) after (ii) exposing the semiconductor substrate to a reducing agent to reduce the metal precursor to metal; and
(iv) repeating steps (i)-(iii) to perform at least 10 inhibitor-assisted deposition cycles.

19. (canceled)

20. The method of claim 1, wherein the metal layer is deposited conformally.

21. The method of claim 1, wherein the metal layer is deposited in a bottom-up deposition mode to fill the recessed feature.

22. The method of claim 1, wherein the method comprises delivering the deposition inhibitor and the metal precursor to a process chamber contemporaneously.

23. An apparatus for processing a substrate, the apparatus comprising:
(a) a process chamber, having a substrate holder for holding a semiconductor substrate, and one or more inlets for introduction of reactants to the process chamber; and
(b) a controller comprising program instructions for:
(i) causing contact of a semiconductor substrate having a recessed feature with a deposition inhibitor, wherein the deposition inhibitor is a halogen-containing compound, and wherein the deposition inhibitor modifies a surface of the semiconductor substrate to make the modified surface more resistant to metal deposition than the surface was before the modification; and
(ii) causing contact of the semiconductor substrate with a metal precursor, and causing a reduction of the metal precursor to form a metal layer at least within the recessed feature on the semiconductor substrate, wherein the metal precursor and the halogen-containing compound are different.
